(19) United States
(12) Patent Application Publication
(10) Pub. No.: US 2026/0089912 A1
(43) Pub. Date: Mar. 26, 2026

(54) SEMICONDUCTOR MEMORY DEVICE

(71) Applicant: Kioxia Corporation, Tokyo (JP)

(72) Inventors: Hidehiro SHIGA, Yokohama Kanagawa (JP); Mutsumi OKAJIMA, Yokkaichi Mie (JP); Takeshi SUGIMOTO, Yokohama Kanagawa (JP); Kenya TASHIRO, Fujisawa Kanagawa (JP)

(73) Assignee: Kioxia Corporation, Tokyo (JP)

(21) Appl. No.: 19/076,096

(22) Filed: Mar. 11, 2025

(30) Foreign Application Priority Data
Sep. 20, 2024 (JP) 2024-163559

(51) Int. Cl. H10B 12/00

(52) U.S. Cl. CPC H10B 12/30; H10B 12/02

(57) ABSTRACT

A semiconductor memory device comprises: first semiconductor layers stacked in a first direction; a via wiring electrically connected to the first semiconductor layers; memory portions electrically connected to the first semiconductor layers; first gate electrodes facing the first semiconductor layers; a first wiring and a second wiring provided on one side and the other side in the first direction with respect to the first semiconductor layers; a second semiconductor layer provided between the first semiconductor layers and the first wiring, and electrically connected to the via wiring; a first connecting electrode electrically connected to the first wiring and the second semiconductor layer; a third semiconductor layer provided between the first semiconductor layers and the second wiring, and electrically connected to the via wiring; and a second connecting electrode electrically connected to the second wiring and the third semiconductor layer.

### CROSS-REFERENCE TO RELATED APPLICATIONS

This application is based upon and claims the benefit of Japanese Patent Application No. 2024-163559, filed on Sep. 20, 2024, the entire contents of which are incorporated herein by reference.

### BACKGROUND

### Field

The present embodiments relate to semiconductor memory devices.

### Description of the Related Art

As degree-of-integration of semiconductor memory devices continues to rise, study is underway into how three-dimensionality of the semiconductor memory devices may be further promoted.

### BRIEF DESCRIPTION OF THE DRAWINGS

FIG. 1 is a schematic circuit diagram showing a part of a configuration of a semiconductor memory device according to a first embodiment;

FIG. 2 is a schematic circuit diagram for explaining a read operation of same semiconductor memory device;

FIG. 3 is a schematic XY cross-sectional view showing a part of a configuration of same semiconductor memory device;

FIG. 4 is a schematic cross-sectional view showing a part of a configuration of same semiconductor memory device;

FIG. 5 is a schematic XY cross-sectional view showing a part of a configuration of same semiconductor memory device;

FIG. 6 is a schematic XZ cross-sectional view showing a part of a configuration of same semiconductor memory device;

FIG. 7 is a schematic cross-sectional view for explaining a method of manufacturing same semiconductor memory device;

FIG. 8 is a schematic cross-sectional view for explaining same method of manufacturing;

FIG. 9 is a schematic cross-sectional view for explaining same method of manufacturing;

FIG. 10 is a schematic cross-sectional view for explaining same method of manufacturing;

FIG. 11 is a schematic cross-sectional view for explaining same method of manufacturing;

FIG. 12 is a schematic cross-sectional view for explaining same method of manufacturing;

FIG. 13 is a schematic cross-sectional view for explaining same method of manufacturing;

FIG. 14 is a schematic cross-sectional view for explaining same method of manufacturing;

FIG. 15 is a schematic cross-sectional view for explaining same method of manufacturing;

FIG. 16 is a schematic cross-sectional view showing a part of a configuration of a semiconductor memory device according to a second embodiment;

FIG. 17 is a schematic cross-sectional view showing a part of a configuration of the semiconductor memory device according to the second embodiment;

FIG. 18 is a schematic circuit diagram showing a part of a configuration of a semiconductor memory device according to a third embodiment;

FIG. 19 is a schematic XY cross-sectional view showing a part of a configuration of the semiconductor memory device according to the third embodiment;

FIG. 20 is a schematic cross-sectional view showing a part of a configuration of the semiconductor memory device according to the third embodiment;

FIG. 21 is a schematic cross-sectional view showing a part of a configuration of a semiconductor memory device according to a fourth embodiment;

FIG. 22 is a schematic circuit diagram showing a part of a configuration of a semiconductor memory device according to a fifth embodiment;

FIG. 23 is a schematic XY cross-sectional view showing a part of a configuration of the semiconductor memory device according to the fifth embodiment;

FIG. 24 is a schematic cross-sectional view showing a part of a configuration of the semiconductor memory device according to the fifth embodiment;

FIG. 25 is a schematic cross-sectional view showing a part of a configuration of a semiconductor memory device according to a sixth embodiment;

FIG. 26 is a schematic cross-sectional view showing a part of a configuration of a semiconductor memory device according to a seventh embodiment; and

FIG. 27 is a schematic XY cross-sectional view showing a part of a configuration of a semiconductor memory device according to another embodiment.

### DETAILED DESCRIPTION

A semiconductor memory device according to one embodiment comprises: a plurality of first semiconductor layers stacked in a first direction; a via wiring which extends in the first direction, and is electrically connected to the plurality of first semiconductor layers; a plurality of memory portions which are arranged in the first direction corresponding to the plurality of first semiconductor layers, and are electrically connected to the plurality of first semiconductor layers; and a plurality of first gate electrodes which are arranged in the first direction corresponding to the plurality of first semiconductor layers, and face the plurality of first semiconductor layers. Moreover, this semiconductor memory device comprises: a first wiring provided on one side in the first direction with respect to the plurality of first semiconductor layers; a second semiconductor layer which is provided between the plurality of first semiconductor layers and the first wiring, and is electrically connected to the via wiring; a first connecting electrode which is provided between the plurality of memory portions and the first wiring, and is electrically connected to the first wiring and the second semiconductor layer; and a second gate electrode which is provided between the plurality of first gate electrodes and the first wiring, and faces the second semiconductor layer. Moreover, this semiconductor memory device comprises: a second wiring provided on the other side in the first direction with respect to the plurality of first semiconductor layers; a third semiconductor layer which is provided between the plurality of first semiconductor layers and the second wiring, and is electrically connected to the via wiring; a second connecting electrode which is provided between the plurality of memory portions and the second wiring, and is electrically connected to the second wiring and the third semiconductor layer; and a third gate electrode which is provided between the plurality of first gate electrodes and the second wiring, and faces the third semiconductor layer.

Next, semiconductor memory devices according to embodiments will be described in detail with reference to the drawings. Note that the following embodiments are merely examples, and are not shown with the intention of limiting the present invention. Moreover, the following drawings are schematic, and, for convenience of description, a part of a configuration, and so on, thereof will sometimes be omitted. Moreover, portions that are common to a plurality of embodiments will be assigned with the same symbols, and descriptions thereof sometimes omitted.

Moreover, when a “semiconductor memory device” is referred to in the present specification, it will sometimes mean a memory die, and will sometimes mean a memory system including a controller die, of the likes of a memory chip, a memory card, or an SSD (Solid State Drive). Furthermore, it will sometimes mean a configuration including a host computer, of the likes of a smartphone, a tablet terminal, or a personal computer.

Moreover, in the present specification, when a first configuration is said to be “electrically connected” to a second configuration, the first configuration may be connected to the second configuration directly, or the first configuration may be connected to the second configuration via the likes of a wiring, a semiconductor member, or a transistor. For example, in the case of three transistors having been connected in series, the first transistor is still “electrically connected” to the third transistor even when the second transistor is in an OFF state.

Moreover, in the present specification, when a first configuration is said to be “electrically connected between” a second configuration and a third configuration, it will sometimes mean that the first configuration, the second configuration, and the third configuration are connected in series, and the second configuration is electrically connected to the third configuration via the first configuration.

Moreover, in the present specification, when a circuit, or the like, is said to “make electrically continuous” two wirings, or the like, this will sometimes mean, for example, that this circuit, or the like, includes a transistor, or the like, that this transistor, or the like, is provided in a current path between the two wirings, and that this transistor, or the like, is in an ON state.

Moreover, in the present specification, a certain direction parallel to an upper surface of a substrate will be referred to as an X-direction, a direction parallel to the upper surface of the substrate and perpendicular to the X-direction will be referred to as a Y-direction, and a direction perpendicular to the upper surface of the substrate will be referred to as a Z-direction.

Moreover, in the present specification, a direction intersecting a certain plane will sometimes be referred to as a first direction, and a direction intersecting the first direction along this plane will sometimes be referred to as a second direction. Moreover, a direction intersecting the second direction along this plane will sometimes be referred to as a third direction. The first direction, the second direction, and the third direction may correspond to any of the X-direction, the Y-direction, and the Z-direction, but need not do so.

Moreover, in the present specification, expressions such as “above” or “below” will be defined with reference to the substrate. For example, an orientation of moving away from the substrate along the above-described Z-direction will be referred to as above, and an orientation of coming closer to the substrate along the Z-direction will be referred to as below. Moreover, when a lower surface or a lower end is referred to for a certain configuration, this will be assumed to mean a surface or end portion on a substrate side of this configuration, and when an upper surface or an upper end is referred to for a certain configuration, this will be assumed to mean a surface or end portion on an opposite side to the substrate of this configuration. Moreover, a surface intersecting the X-direction or the Y-direction will be referred to as a side surface, and so on.

Moreover, in the present specification, when a “center position” of a certain configuration is referred to, it may mean a position of the center of a circumscribed circle of this configuration, or may mean the center of gravity on an image of this configuration, for example.

### First Embodiment

### Circuit Configuration

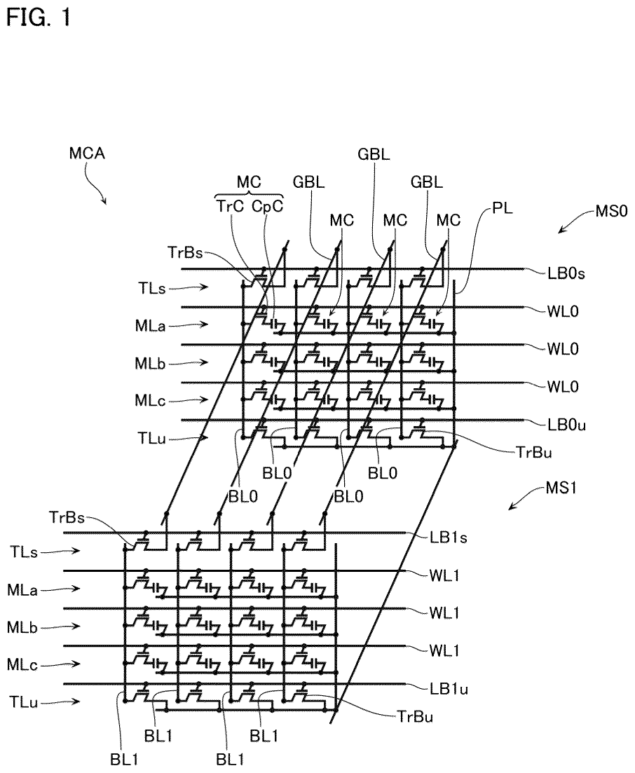

FIG. 1 is a schematic circuit diagram showing a part of a configuration of a semiconductor memory device according to a first embodiment. As shown in FIG. 1, the semiconductor memory device according to the present embodiment comprises a memory cell array MCA. The memory cell array MCA comprises a plurality of memory structures MS. In FIG. 1, two of these plurality of memory structures MS are exemplified as memory structures MS0, MS1. Moreover, the memory cell array MCA comprises a plurality of global bit lines GBL and a plate line PL that are connected to these plurality of memory structures MS. The plurality of memory structures MS each comprise a plurality of memory layers ML. In FIG. 1, three of these plurality of memory layers ML are exemplified as memory layers MLa-MLc. In addition, the plurality of memory structures MS each comprise: transistor layers TLs, TLu; and a plurality of bit lines BL connected to these plurality of memory layers ML and to the transistor layers TLs, TLu. Hereafter, bit lines BL in the memory structure MS0 will sometimes be referred to as “bit lines BL0”, and bit lines BL in the memory structure MS1 will sometimes be referred to as “bit lines BL1”.

The memory layers ML each comprise: a word line WL; and a plurality of memory cells MC connected to the word line WL. Hereafter, a word line WL in the memory structure MS0 will sometimes be referred to as a “word line WL0”, and a word line WL in the memory structure MS1 will sometimes be referred to as a “word line WL1”. The memory cells MC each comprise a transistor TrC and a capacitor CpC. One electrode of the transistor TrC is connected to the bit line BL. The other electrode of the transistor TrC is connected to the capacitor CpC. Note that the one and the other electrodes of the transistor TrC function as a source electrode or drain electrode, according to a voltage applied to the transistor TrC. A gate electrode of the transistor TrC is connected to the word line WL. One electrode of the capacitor CpC is connected to the other electrode of the transistor TrC. The other electrode of the capacitor CpC is connected to the plate line PL.

The bit lines BL are each connected to a plurality of the memory cells MC corresponding to the plurality of memory layers ML.

The transistor layer TLs comprises: a bit line select line LBs; and a plurality of transistors TrBs connected to the bit line select line LBs. Hereafter, a bit line select line LBs in the memory structure MS0 will sometimes be referred to as a “bit line select line LB0s”, and a bit line select line LBs in the memory structure MS1 will sometimes be referred to as a “bit line select line LB1s”. One electrode of the transistor TrBs is connected to the global bit line GBL. The other electrode of the transistor TrBs is connected to the bit line BL. Note that the one and the other electrodes of the transistor TrBs function as a source electrode or drain electrode, according to a voltage applied to the transistor TrBs. A gate electrode of the transistor TrBs is connected to the bit line select line LBs.

The transistor layer TLu comprises: a bit line select line LBu; and a plurality of transistors TrBu connected to the bit line select line LBu. Hereafter, a bit line select line LBu in the memory structure MS0 will sometimes be referred to as a “bit line select line LB0u”, and a bit line select line LBu in the memory structure MS1 will sometimes be referred to as a “bit line select line LB1u”. One electrode of the transistor TrBu is connected to the plate line PL. The other electrode of the transistor TrBu is connected to the bit line BL. Note that the one and the other electrodes of the transistor TrBu function as a source electrode or drain electrode, according to a voltage applied to the transistor TrBu. A gate electrode of the transistor TrBu is connected to the bit line select line LBu.

### Read Operation

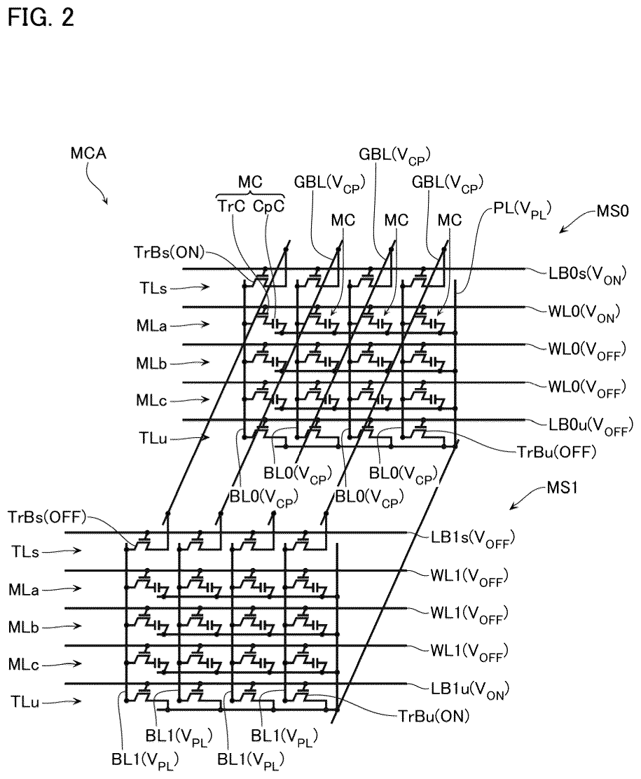

FIG. 2 is a schematic circuit diagram for explaining a read operation of the semiconductor memory device according to the first embodiment.

During the read operation, one of the plurality of memory structures MS is selected. Moreover, one of the plurality of memory layers ML in the selected memory structure MS is selected. An example where the memory layer MLa in the memory structure MS0 is selected, will be described below.

For example, in the example illustrated, in the selected memory structure MS0, the word line WL0 in the memory layer MLa is applied with a voltage V_{ON}, and the word lines WL0 in the memory layers MLb, MLc which have not been selected, are applied with a voltage V_{OFF}. As a result, the transistors TrC in the memory layer MLa will attain an ON state, and the transistors TrC in the memory layers MLb, MLc which have not been selected, will attain an OFF state. Moreover, in the example illustrated, the bit line select line LB0s in the transistor layer TLs is applied with the voltage V_{ON}, and the bit line select line LB0u in the transistor layer TLu is applied with the voltage V_{OFF}. As a result, the bit lines BL0 will be electrically continuous with the global bit lines GBL, and electrically isolated from the plate line PL.

Hence, the capacitor CpC in the memory cell MC which is target of the read operation (hereafter, sometimes called “selected memory cell MC”) will be electrically continuous with the global bit line GBL via the bit line BL. Consequently, voltages of the global bit lines GBL will fluctuate, or a current will flow in the global bit lines GBL. Detecting this voltage fluctuation or current enables data stored in the selected memory cell MC to be read. In FIG. 2, voltages of the global bit lines GBL are exemplified as a voltage V_{CP}.

Moreover, in the example illustrated, in the memory structure MS1 which has not been selected, the word lines WL1 in all of the memory layers MLa, MLb, MLc are applied with the voltage V_{OFF}. As a result, the transistors TrC in all of the memory layers MLa, MLb, MLc will attain an OFF state. Moreover, in the example illustrated, the bit line select line LB1s in the transistor layer TLs is applied with the voltage V_{OFF}, and the bit line select line LB1u in the transistor layer TLu is applied with the voltage V_{ON}. As a result, the bit lines BL1 will be electrically isolated from the global bit line GBL, and electrically continuous with the plate line PL.

Hence, the bit lines BL1 will be applied with a voltage V_{PL} of the plate line PL. As a result, voltages of the bit lines BL will be fixed, thereby enabling deterioration of charge holding characteristics of the memory cells MC to be suppressed.

Note that the voltage V_{ON} has a magnitude of a degree that the transistors TrC, TrBs, TrBu will be set to an ON state. The voltage V_{OFF} has a magnitude of a degree that the transistors TrC, TrBs, TrBu will be set to an OFF state. For example, in the case of the transistors TrC, TrBs, TrBu being NMOS transistors, voltage V_{ON} will be greater than voltage V_{OFF}. Moreover, for example, in the case of the transistors TrC, TrBs, TrBu being PMOS transistors, voltage V_{ON} will be less than voltage V_{OFF}.

### Structure

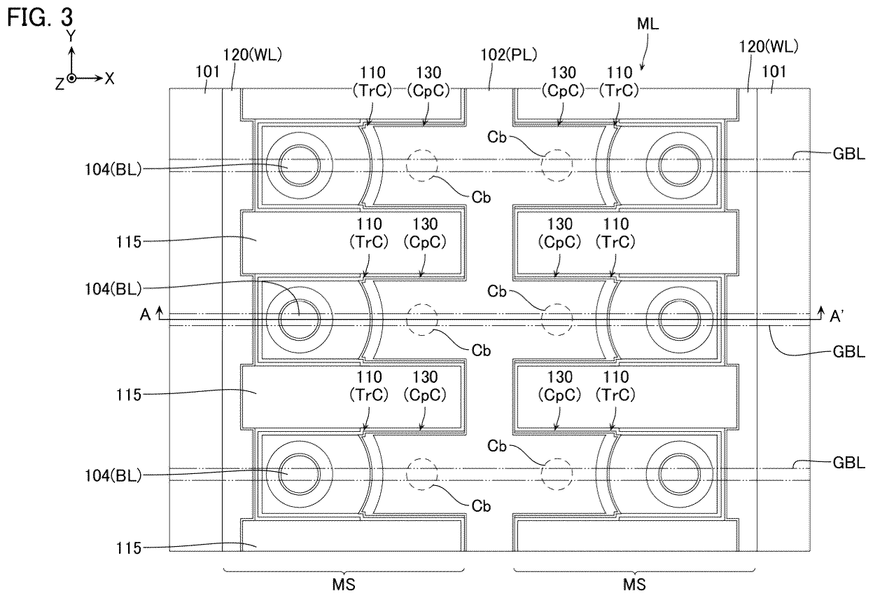

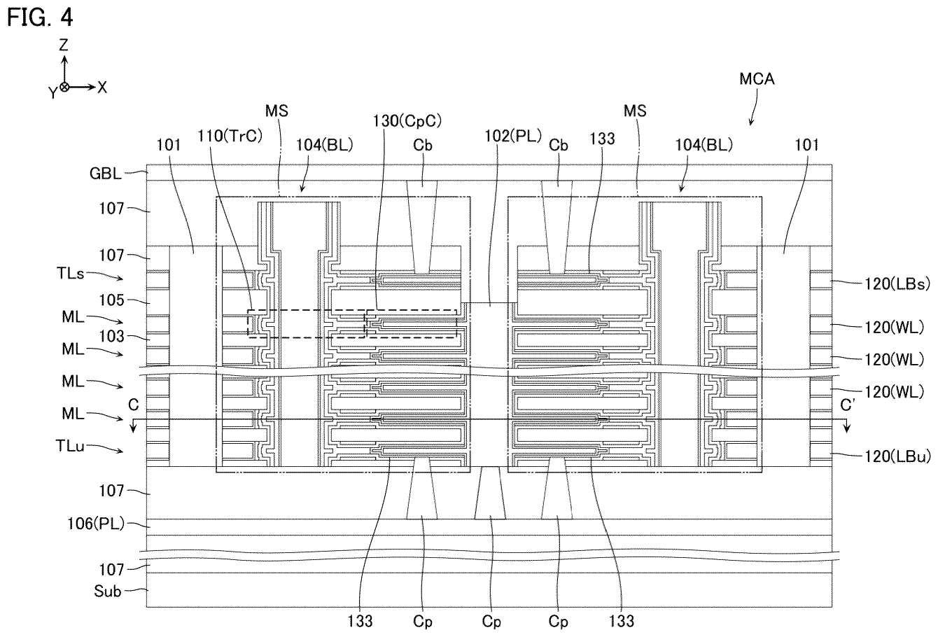

FIG. 3 is a schematic XY cross-sectional view showing a part of a configuration of the semiconductor memory device according to the present embodiment. FIG. 4 is a schematic cross-sectional view showing a part of a configuration of the semiconductor memory device according to the present embodiment. FIG. 3 shows a view in which the structure shown in FIG. 4 has been cut along the line C-C′ and viewed along a direction of the arrows. Moreover, in FIG. 3, the global bit line GBL is indicated by a two dot-chain line, and a later-mentioned contact electrode Cb is indicated by a dotted line. FIG. 4 shows a view in which the structure shown in FIG. 3 has been cut along the line A-A′ and viewed along a direction of the arrows.

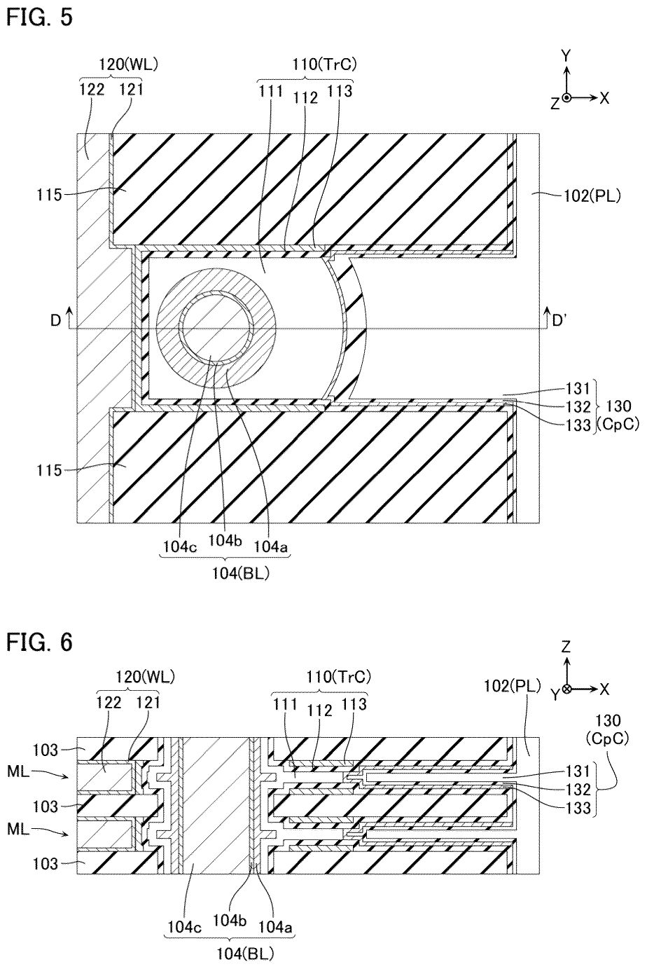

FIG. 5 is a schematic XY cross-sectional view showing a part of a configuration of the semiconductor memory device according to the present embodiment. FIG. 5 shows part of FIG. 3 enlarged. FIG. 6 is a schematic XZ cross-sectional view showing a part of a configuration of the semiconductor memory device according to the present embodiment. FIG. 6 shows a view in which the structure shown in FIG. 5 has been cut along the line D-D′ and viewed along a direction of the arrows.

As shown in FIG. 4, the semiconductor memory device according to the present embodiment comprises a semiconductor substrate Sub which is provided below the memory cell array MCA. The semiconductor substrate Sub includes the likes of silicon (Si) containing a P-type impurity such as boron (B), for example. An unillustrated insulating layer and unillustrated electrode layer are provided on an upper surface of the semiconductor substrate Sub. The upper surface of the semiconductor substrate Sub, and the unillustrated insulating layer and electrode layer configure a control circuit for controlling the semiconductor memory device according to the first embodiment. For example, a region directly below the memory cell array MCA is provided with a sense amplifier circuit. The sense amplifier circuit is electrically connected to the bit line BL via the global bit line GBL. The sense amplifier circuit is capable of detecting voltage fluctuation or current of the bit line BL in the read operation, and thereby read data stored in the selected memory cell MC in the read operation.

The memory cell array MCA comprises a plurality of the memory structures MS arranged in the X-direction. Moreover, a conductive layer 102 is provided between the 2n+1^{th} (where n is an integer of 0 or more) memory structure MS counting from one side in the X-direction and the 2n+2^{th} memory structure MS counting from the one side in the X-direction. Moreover, an insulating layer 101 of the likes of silicon oxide (SiO) is provided between the 2n+2^{th} memory structure MS counting from the one side in the X-direction and the 2n+3^{th} memory structure MS counting from the one side in the X-direction. Moreover, the global bit line GBL is provided above the plurality of memory structures MS, and a conductive layer 106 acting as part of the plate line PL is provided below the plurality of memory structures MS.

Moreover, an insulating layer 107 of the likes of silicon oxide (SiO) is provided between the global bit line GBL and the plurality of memory structures MS, between the conductive layer 106 (the plate line PL) and the plurality of memory structures MS, and below the conductive layer 106.

### Structure of Memory Structure MS

As shown in FIG. 3, the memory structure MS comprises a plurality of via wirings 104 and a plurality of insulating layers 115 that are arranged alternately in the Y-direction. Moreover, as shown in FIG. 4, the memory structure MS comprises: a plurality of the memory layers ML stacked in the Z-direction; the transistor layer TLs provided above the plurality of memory layers ML; and the transistor layer TLu provided below the plurality of memory layers ML.

Moreover, an insulating layer 103 of the likes of silicon oxide (SiO) is provided between each of the plurality of memory layers ML and between the lowermost layer memory layer ML and transistor layer TLu. An insulating layer 105 of the likes of silicon oxide (SiO) is provided between the uppermost layer memory layer ML and transistor layer TLs. A thickness of the insulating layer 105 in the Z-direction is greater than a thickness of the insulating layer 103 in the Z-direction.

As shown in FIG. 4, for example, the via wiring 104 extends in the Z-direction penetrating the plurality of memory layers ML and the transistor layers TLs, TLu. As shown in FIG. 6, the via wiring 104 includes, for example: a conductive oxide film 104a including a conductive oxide; a barrier conductive film 104b of the likes of titanium nitride (TiN); and a conductive member 104c of the likes of tungsten (W). Note that the via wiring 104 may include ruthenium (Ru), iridium (Ir), or another metal, instead of the conductive oxide film 104a. Moreover, the via wiring 104 may include solely a conductive oxide, or may include solely ruthenium (Ru), iridium (Ir), or another metal.

In the present specification, a “conductive oxide” is assumed to include indium tin oxide (ITO), indium zinc oxide (IZO), ruthenium oxide (RuO₂), iridium oxide (IrO₂), or another conductive material including oxygen, for example.

The conductive member 104c comprises a substantially circular column-like shape extending in the Z-direction. The barrier conductive film 104b comprises a substantially cylindrical shape extending in the Z-direction along an outer peripheral surface of the conductive member 104c. The conductive oxide film 104a comprises a substantially cylindrical shape extending in the Z-direction along an outer peripheral surface of the barrier conductive film 104b.

The via wiring 104 functions as the bit line BL (FIG. 1), for example. As shown in FIG. 1, for example, a plurality of the bit lines BL are provided corresponding to pluralities of the transistors TrC included in the memory layers ML.

The insulating layer 115 includes the likes of silicon oxide (SiO). The insulating layer 115 extends in the Z-direction penetrating the plurality of memory layers ML and the transistor layers TLs, TLu.

### Structure of Memory Layer ML

As shown in FIG. 3, for example, the memory layer ML comprises: a plurality of transistor structures 110 arranged in the Y-direction corresponding to the plurality of via wirings 104; a conductive layer 120 provided between the plurality of transistor structures 110 and the insulating layer 101; and a plurality of capacitor structures 130 provided between the plurality of transistor structures 110 and the conductive layer 102.

As shown in FIGS. 5 and 6, for example, the transistor structure 110 comprises: a semiconductor layer 111 connected to an outer peripheral surface of the via wiring 104 and extending in the X-direction; an insulating layer 112 provided on an upper surface, a lower surface, both side surfaces in the Y-direction, and a side surface on one side (a conductive layer 120 side) in the X-direction of the semiconductor layer 111; and a conductive layer 113 provided on an upper surface, a lower surface, both side surfaces in the Y-direction, and a side surface on one side (the conductive layer 120 side) in the X-direction of the insulating layer 112.

In an XY cross section of the kind exemplified in FIG. 5, a side surface of the semiconductor layer 111 on one side (a conductive layer 102 side) in the X-direction may be formed along a circle centered on a center position of the via wiring 104. Moreover, side surfaces of the semiconductor layer 111, insulating layer 112, and conductive layer 113 on the other side (the conductive layer 120 side) in the X-direction may be formed linearly along a side surface of the conductive layer 120. Moreover, both side surfaces in the Y-direction of the semiconductor layer 111, insulating layer 112, and conductive layer 113 may be formed linearly along side surfaces of the insulating layers 115.

The semiconductor layer 111 functions as a channel region of the transistor TrC (FIG. 1). The semiconductor layer 111 may be, for example, a semiconductor including: at least one element of gallium (Ga) or aluminum (Al); indium (In); zinc (Zn); and oxygen (O), or may be, for example, another oxide semiconductor. A plurality of the semiconductor layers 111 arranged in the Z-direction are commonly connected to the via wiring 104 extending in the Z-direction.

The insulating layer 112 functions as a gate insulating film of the transistor TrC (FIG. 1). The insulating layer 112 includes the likes of silicon oxide (SiO), for example.

The conductive layer 113 functions as the gate electrode of the transistor TrC (FIG. 1). The conductive layer 113 includes titanium nitride (TiN) or a conductive oxide such as indium tin oxide (ITO), for example. A plurality of the conductive layers 113 arranged in the Y-direction are commonly connected to the conductive layer 120 extending in the Y-direction (refer to FIG. 5). The conductive layer 113 faces the upper surface, the lower surface, both side surfaces in the Y-direction, and the side surface on one side (the conductive layer 120 side) in the X-direction of the semiconductor layer 111, via the insulating layer 112.

The conductive layer 120 functions as the word line WL (FIG. 1). The conductive layer 120 extends in the Y-direction, and is connected to a plurality of the conductive layers 113 arranged in the Y-direction. The conductive layer 120 comprises: a barrier conductive film 121 of the likes of titanium nitride (TiN), for example; and a conductive film 122 of tungsten (W).

As shown in FIGS. 5 and 6, for example, the capacitor structure 130 comprises: a conductive layer 131; an insulating layer 132 provided on an upper surface, a lower surface, both side surfaces in the Y-direction, and a side surface on one side (a transistor structure 110 side) in the X-direction of the conductive layer 131; and a conductive layer 133 provided on an upper surface, a lower surface, both side surfaces in the Y-direction, and a side surface on one side (the transistor structure 110 side) in the X-direction of the insulating layer 132.

The conductive layer 131 functions as one electrode of the capacitor CpC (FIG. 1). The conductive layer 131 can include the likes of a stacked structure of titanium nitride (TiN) and tungsten (W), for example. Moreover, the conductive layer 131 may include a conductive oxide, for example. Note that the conductive layer 131 may include ruthenium (Ru), iridium (Ir), or another metal, instead of the conductive oxide. Moreover, the conductive layer 131 may include solely a conductive oxide, or may include solely ruthenium (Ru), iridium (Ir), or another metal. The conductive layer 131 is continuous with the conductive layer 102.

The insulating layer 132 functions as an insulating layer of the capacitor CpC (FIG. 1). The insulating layer 132 may be zirconia (ZrO₂), alumina (Al₂O₃), or another insulating metal oxide, for example. Moreover, the insulating layer 132 may be for example a stacked film of a plurality of insulating metal oxides (for example, a stacked film of zirconia and alumina).

The conductive layer 133 functions as the other electrode of the capacitor CpC (FIG. 1). The conductive layer 133 includes a conductive oxide such as indium tin oxide (ITO), for example. The conductive layer 133 faces the upper surface, the lower surface, both side surfaces in the Y-direction, and the side surface on one side (the conductive layer 120 side) in the X-direction of the conductive layer 131, via the insulating layer 132. The conductive layer 133 is connected to a side surface of the semiconductor layer 111 in the X-direction.

### Structure of Transistor Layer TLs

As shown in FIG. 4, the transistor layer TLs is basically configured similarly to the memory layer ML. However, the conductive layer 133 in the transistor layer TLs is connected to the global bit line GBL via a contact electrode Cb. Moreover, a position of an upper end of the conductive layer 102 in the Z-direction is provided between the uppermost layer memory layer ML and the transistor layer TLs, and the conductive layer 131 in the transistor layer TLs is separated from the conductive layer 102.

The semiconductor layer 111 in the transistor layer TLs functions as a channel region of the transistor TrBs (FIG. 1). The insulating layer 112 in the transistor layer TLs functions as a gate insulating film of the transistor TrBs (FIG. 1). The conductive layer 113 in the transistor layer TLs functions as the gate electrode of the transistor TrBs (FIG. 1). The conductive layer 120 in the transistor layer TLs functions as the bit line select line LBs (FIG. 1). The conductive layer 133 in the transistor layer TLs functions as a connecting electrode for electrically connecting the above-described one electrode of the transistor TrBs and the global bit line GBL. These configurations in the transistor layer TLs are provided at respective positions overlapping configurations corresponding to them in the memory layer ML, viewed in the Z-direction.

### Structure of Transistor Layer TLu

The transistor layer TLu is basically configured similarly to the memory layer ML. However, as shown in FIG. 4, the conductive layer 133 in the transistor layer TLu is connected to the plate line PL via a contact electrode Cp.

The semiconductor layer 111 in the transistor layer TLu functions as a channel region of the transistor TrBu (FIG. 1). The insulating layer 112 in the transistor layer TLu functions as a gate insulating film of the transistor TrBu (FIG. 1). The conductive layer 113 in the transistor layer TLu functions as the gate electrode of the transistor TrBu (FIG. 1). The conductive layer 120 in the transistor layer TLu functions as the bit line select line LBu (FIG. 1). The conductive layer 133 in the transistor layer TLu functions as a connecting electrode for electrically connecting the above-described one electrode of the transistor TrBu and the plate line PL. These configurations in the transistor layer TLu are provided at respective positions overlapping configurations corresponding to them in the memory layer ML, viewed in the Z-direction.

### Structure of Conductive Layer 102

The conductive layer 102 can include the likes of a stacked structure of titanium nitride (TiN) and tungsten (W), for example. Moreover, the conductive layer 102 may include a conductive oxide, for example. Note that the conductive layer 102 may include ruthenium (Ru), iridium (Ir), or another metal, instead of the conductive oxide. Moreover, the conductive layer 102 may include solely a conductive oxide, or may include solely ruthenium (Ru), iridium (Ir), or another metal. The conductive layer 102 functions as part of the plate line PL (FIG. 1).

### Structure of Global Bit Line GBL

As shown in FIG. 3, the global bit lines GBL are arranged in the Y-direction and extend in the X-direction to be electrically connected to the conductive layers 133 in the capacitor structures 130 included in the transistor layer TLs. In the example illustrated, the global bit line GBL is provided at a position that, viewed in the Z-direction, overlaps its corresponding plurality of capacitor structures 130. Moreover, the contact electrodes Cb are provided at positions where the global bit line GBL and capacitor structures 130 overlap viewed in the Z-direction. The contact electrodes Cb exemplified in FIG. 4 have upper ends connected to the global bit line GBL, and have lower ends connected to the capacitor structure 130, more specifically, to the conductive layer 133 in the transistor layer TLs.

### Structure of Conductive Layer 106

The conductive layer 106 (FIG. 4) is provided over a region overlapping all of the memory structures MS and all of the conductive layers 102 in the memory cell array MCA, viewed in the Z-direction. The contact electrodes Cp are provided at positions where the conductive layer 106 and capacitor structures 130 overlap viewed in the Z-direction. Such contact electrodes Cp have lower ends connected to the conductive layer 106, and have upper ends connected to the capacitor structures 130, more specifically, to the conductive layers 133 in the transistor layer TLu. Moreover, the contact electrode Cp is also provided at a position where the conductive layer 106 and conductive layer 102 overlap viewed in the Z-direction. Such a contact electrode Cp has its lower end connected to the conductive layer 106, and has its upper end connected to the conductive layer 102.

### Method of Manufacturing

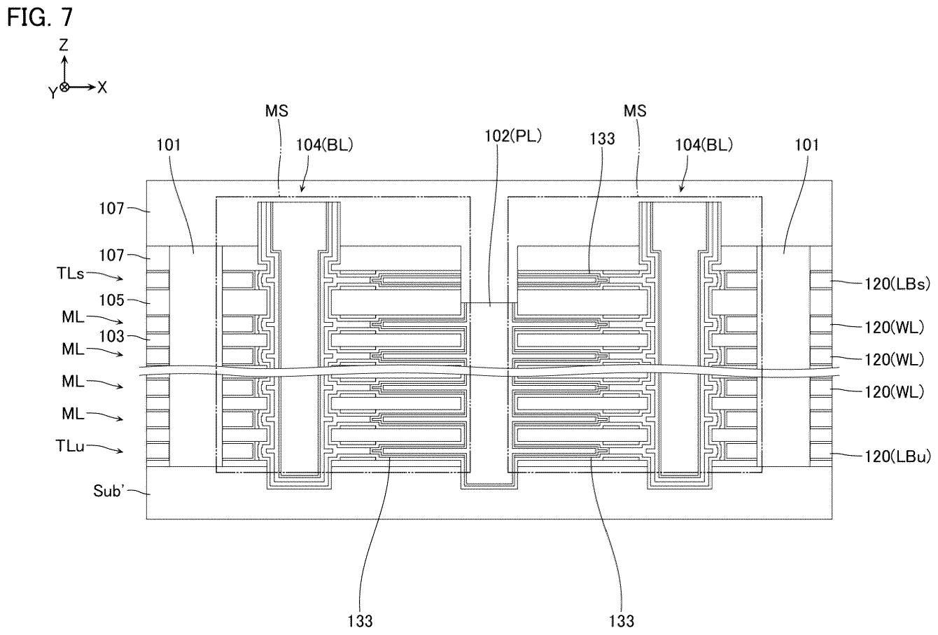

FIGS. 7 to 15 are schematic cross-sectional views for explaining a method of manufacturing the semiconductor memory device according to the first embodiment, and show cross sections corresponding to FIG. 4.

In the method of manufacturing, as shown in FIG. 7, for example, a plurality of the memory structures MS are formed on a substrate Sub′.

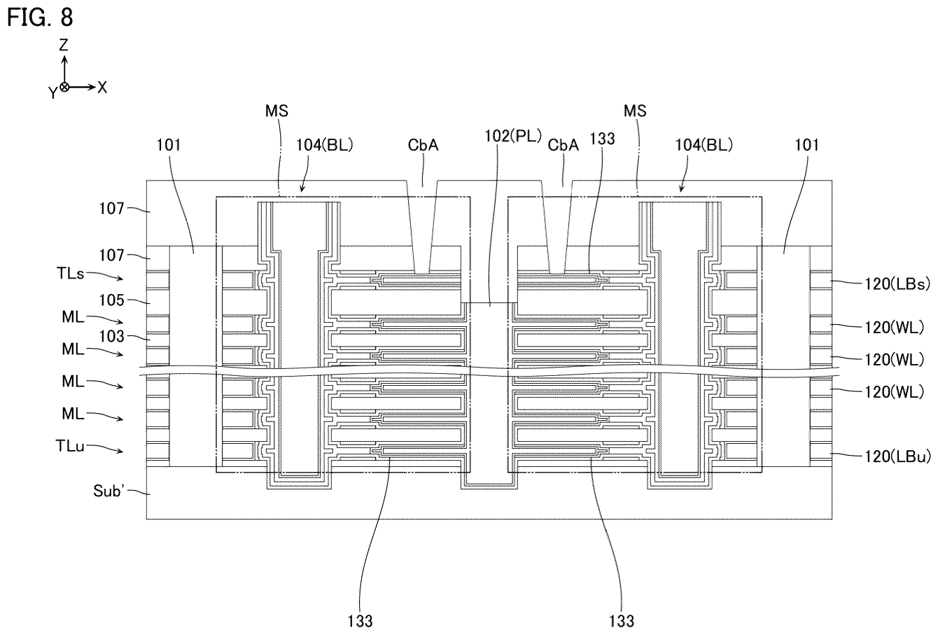

Next, as shown in FIG. 8, for example, openings CbA are formed at positions corresponding to the contact electrodes Cb. The opening CbA extends in the Z-direction and penetrates the insulating layer 107 to expose the conductive layer 133 in the transistor layer TLs. This step is performed by the likes of RIE (Reactive Ion Etching), for example.

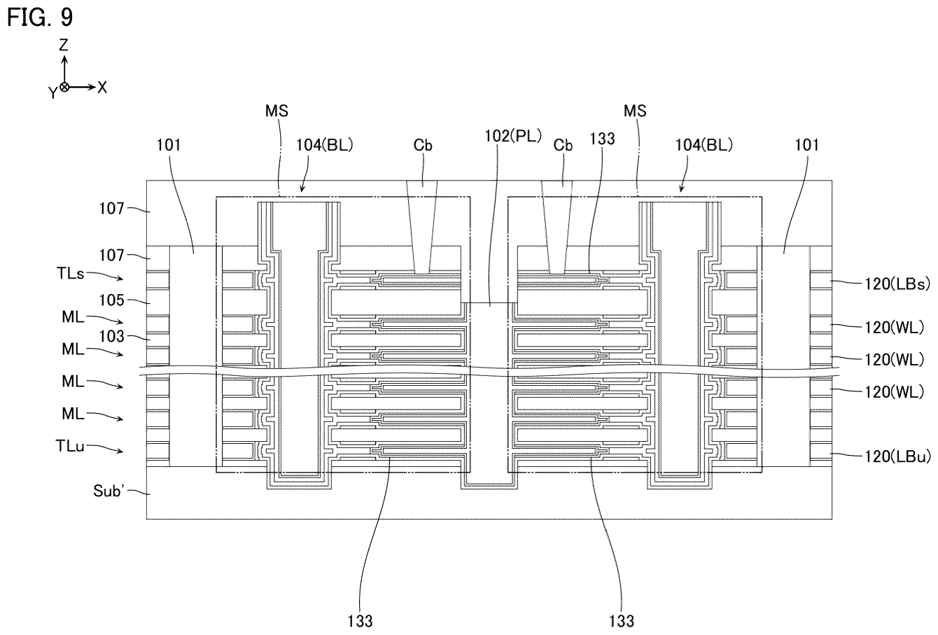

Next, as shown in FIG. 9, for example, the contact electrodes Cb are formed inside the openings CbA. This step is performed by the likes of CVD (Chemical Vapor Deposition), for example.

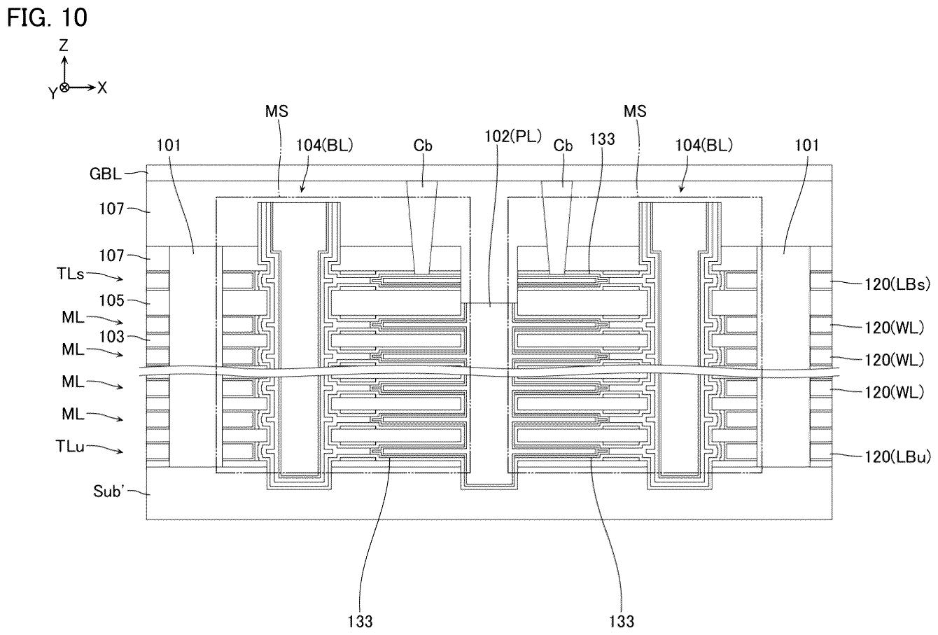

Next, as shown in FIG. 10, for example, the global bit line GBL is formed on exposed surfaces of the insulating layer 107 and contact electrode Cb. This step is performed by the likes of CVD, for example.

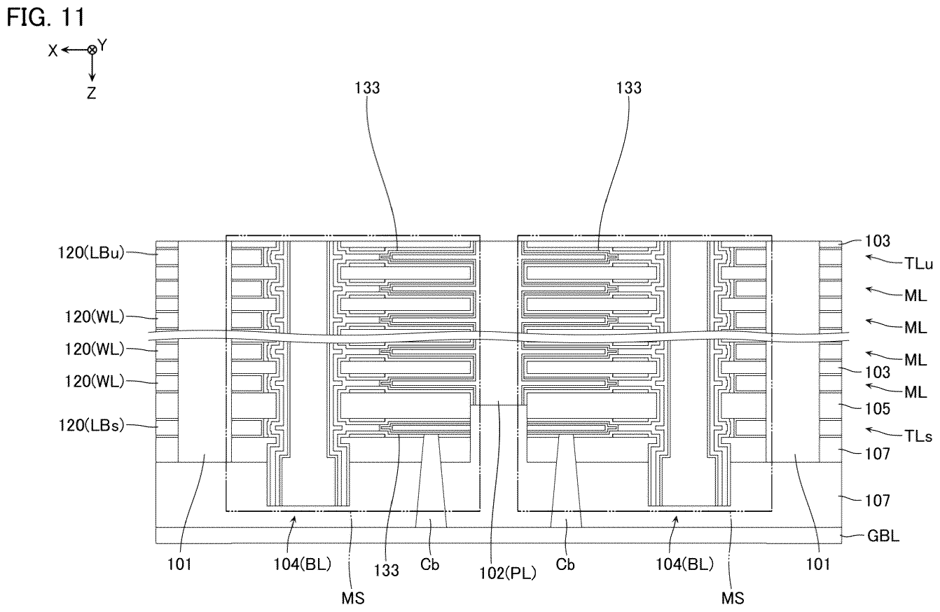

Next, as shown in FIG. 11, for example, the substrate Sub′ is removed to expose the insulating layers 103, the via wirings 104, and the conductive layer 102. This step is performed by a means such as CMP (Chemical Mechanical Polishing), for example.

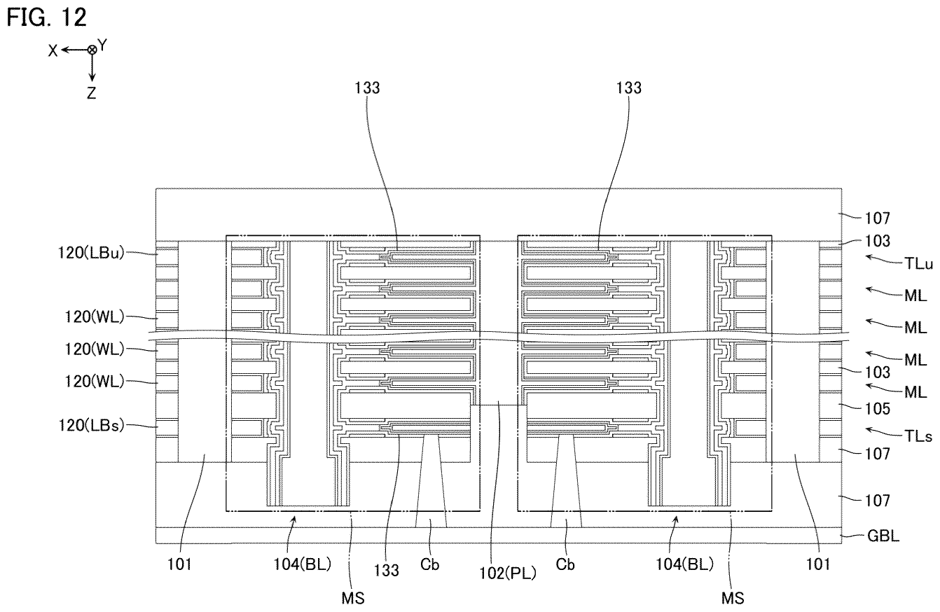

Next, as shown in FIG. 12, for example, the insulating layer 107 is formed on exposed surfaces of the insulating layers 103, the via wirings 104, and the conductive layer 102. This step is performed by a means such as CVD, for example.

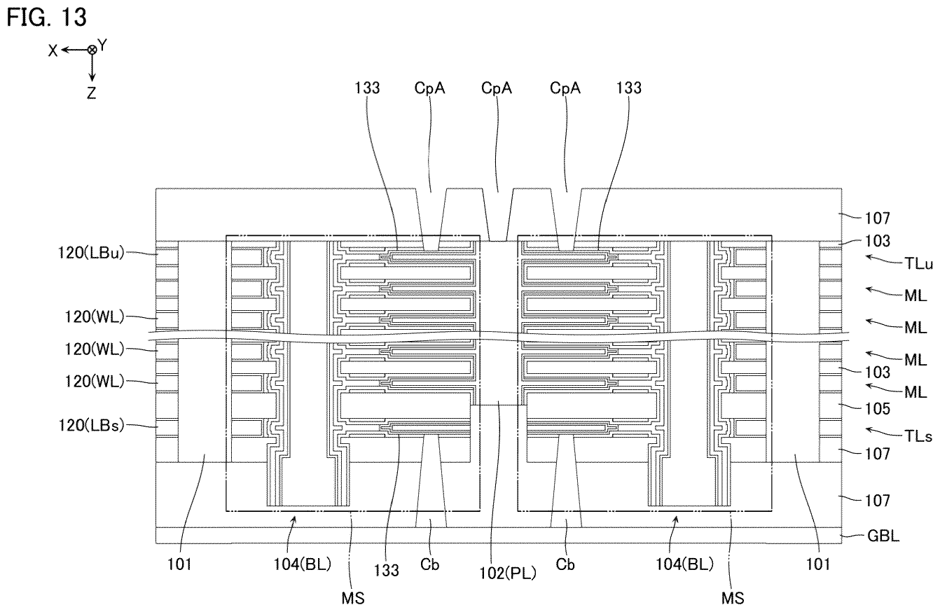

Next, as shown in FIG. 13, for example, openings CpA are formed at positions corresponding to the contact electrodes Cp. The openings CpA extend in the Z-direction and penetrate the insulating layer 107 to expose the conductive layers 133 in the transistor layer TLu, and conductive layer 102. This step is performed by the likes of RIE, for example.

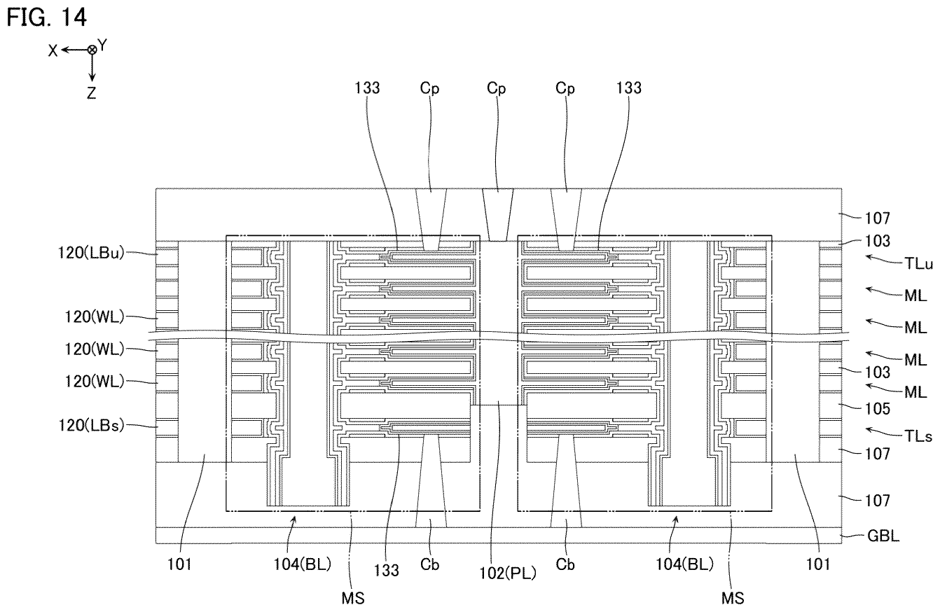

Next, as shown in FIG. 14, for example, the contact electrodes Cp are formed inside the openings CpA. This step is performed by the likes of CVD, for example.

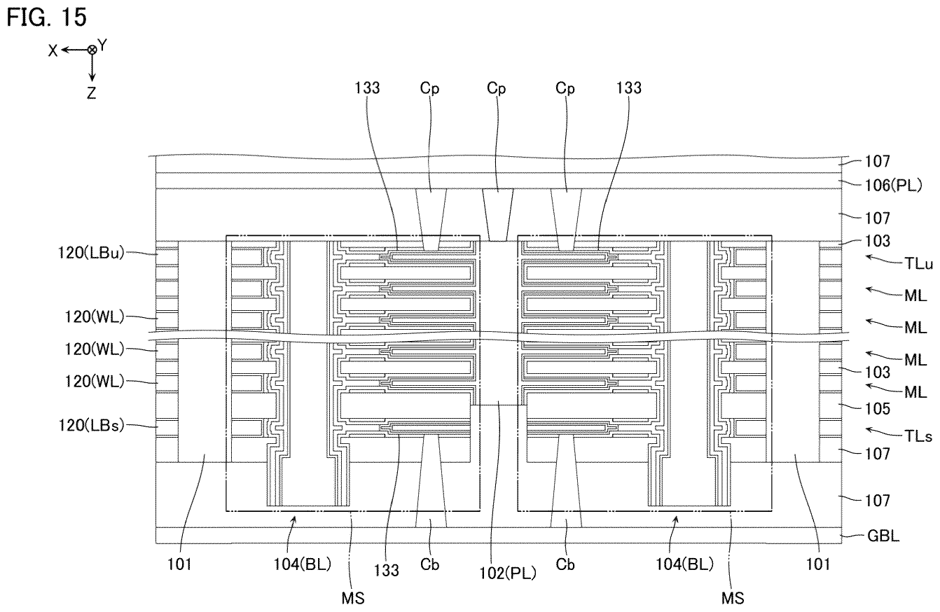

Next, as shown in FIG. 15, for example, the conductive layer 106 and the insulating layer 107 are formed on exposed surfaces of the insulating layer 107 and the contact electrodes Cp. This step is performed by the likes of CVD, for example.

Subsequently, the formed wafer is bonded to a wafer including the semiconductor substrate Sub (a wafer having the peripheral circuit formed therein), and division into individual pieces performed by a means such as dicing, whereby the semiconductor memory device according to the first embodiment is formed. Note that in the present embodiment, the wafer including the semiconductor substrate Sub is bonded to the insulating layer 107. However, an insulating film may be provided on the global bit line GBL, and bonding performed via this insulating film.

### Advantages

The bit line BL according to the present embodiment is electrically connected to the global bit line GBL via the transistor TrBs, and is electrically connected to the plate line PL via the transistor TrBu. Due to such a configuration, as described with reference to FIG. 2, and so on, it is possible for voltage of the bit lines BL in a memory structure MS that has not been selected during the read operation to be fixed, and for deterioration of charge holding characteristics of the memory cells MC to thereby be suppressed.

Now, it is conceivable that, when realizing the transistors TrBs, TrBu according to the present embodiment, a similar structure to that of the memory layer ML will be adopted, for example, and that, as a result, the transistors TrBs, TrBu will be formed with practically no increase in the number of manufacturing steps.

Accordingly, in the present embodiment, the opening CbA is formed to expose the conductive layer 133 in the transistor layer TLs in the step described with reference to FIG. 8, and, in the step described with reference to FIG. 9, the contact electrode Cb connected to the exposed surface of this conductive layer 133, is formed.

Moreover, in the present embodiment, the substrate Sub′ is removed to expose the conductive layer 102 in the step described with reference to FIG. 11, the opening CpA is formed to expose the conductive layer 133 in the transistor layer TLu, and conductive layer 102 in the step described with reference to FIG. 13, and, in the step described with reference to FIG. 14, the contact electrodes Cp connected to the exposed surfaces of these conductive layers 102, 133, are formed.

Due to this kind of method, it is possible for the transistors TrBs, TrBu to be formed with practically no increase in the number of manufacturing steps. That is, it is possible for an easily manufacturable semiconductor memory device to be provided.

### Second Embodiment

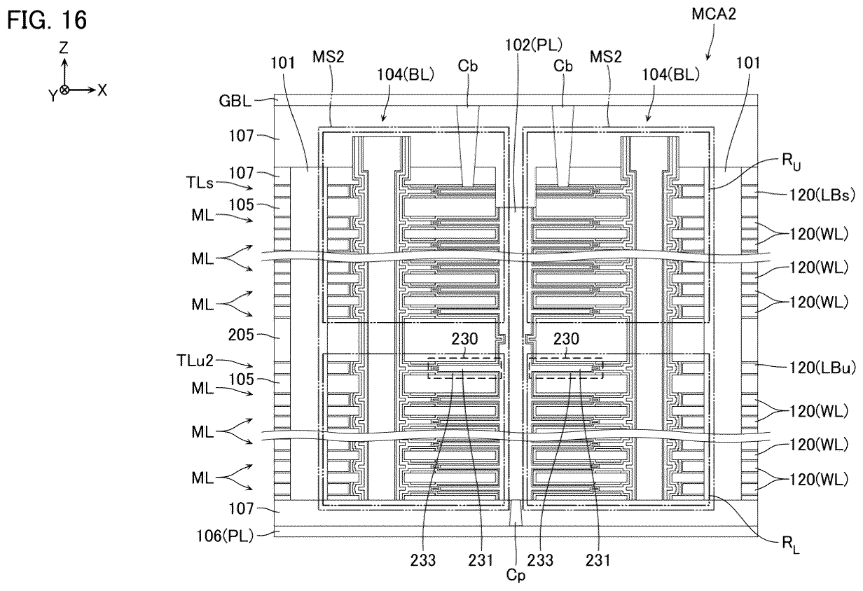

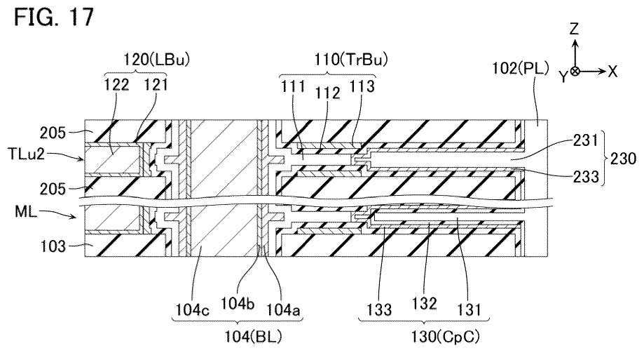

FIGS. 16 and 17 are schematic cross-sectional views showing a part of a configuration of a semiconductor memory device according to a second embodiment. In FIG. 17, parts of the configurations shown in FIG. 16 are shown enlarged. In the following description, portions similar to in the first embodiment will be assigned with the same symbols as in the first embodiment, and descriptions thereof omitted.

The semiconductor memory device according to the second embodiment comprises a memory cell array MCA2. The memory cell array MCA2 is basically configured similarly to the memory cell array MCA. However, as shown in FIG. 16, the memory cell array MCA2 comprises a memory structure MS2 instead of the memory structure MS. Moreover, the semiconductor memory device according to the second embodiment does not comprise the contact electrodes Cp connected to the conductive layer 106, and to the conductive layers 133 in the transistor layer TLu.

The memory structure MS2 comprises the plurality of via wirings 104 and the plurality of insulating layers 115 arranged alternately in the Y-direction, similarly to the memory structure MS. In addition, the memory structure MS2 comprises two regions R_{L}, R_{U} arranged in the Z-direction. The region R_{U} is provided above the region R_{L}. Moreover, an insulating layer 205 of the likes of silicon oxide (SiO) is provided between the regions R_{L}, R_{U}. A thickness of the insulating layer 205 in the Z-direction is greater than a thickness of the insulating layer 105 in the Z-direction.

The region R_{L} comprises: a plurality of the memory layers ML stacked in the Z-direction; and a transistor layer TLu2 provided above the plurality of memory layers ML. The region R_{U} comprises: a plurality of the memory layers ML stacked in the Z-direction; and the transistor layer TLs provided above the plurality of memory layers ML.

The transistor layer TLu2 is basically configured similarly to the memory layer ML. However, the transistor layer TLu2 comprises a structure 230 instead of the capacitor structure 130.

The structure 230 functions as a connecting electrode for electrically connecting the above-described one electrode of the transistor TrBu and the plate line PL. The structure 230 has its one end portion in the X-direction connected to the semiconductor layer 111 in the transistor layer TLu2, and has its other end portion in the X-direction connected to the conductive layer 102.

As shown in FIG. 17, for example, the structure 230 comprises: a conductive layer 231; and a conductive layer 233 provided on an upper surface, a lower surface, both side surfaces in the Y-direction, and a side surface on one side (the transistor structure 110 side) in the X-direction of the conductive layer 231.

The conductive layer 231 is configured similarly to the conductive layer 131. The conductive layer 231 is provided at a position overlapping the conductive layer 131 and insulating layer 132 in the memory layer ML, viewed in the Z-direction.

The conductive layer 233 is basically configured similarly to the conductive layer 133. However, the conductive layer 233 contacts the upper surface, the lower surface, both side surfaces in the Y-direction, and the side surface on one side (the transistor structure 110 side) in the X-direction of the conductive layer 231. The conductive layer 233 is provided at a position overlapping the conductive layer 133 in the memory layer ML, viewed in the Z-direction.

It is possible for this kind of structure to be formed by a manufacturing step where after formation of the insulating layer 132 but before formation of the conductive layer 131, the insulating layer 132 in the transistor layer TLu2 is removed, for example.

Due to this kind of method, too, it is possible for the transistors TrBs, TrBu to be formed with practically no increase in the number of manufacturing steps. That is, it is possible for an easily manufacturable semiconductor memory device to be provided.

### Third Embodiment

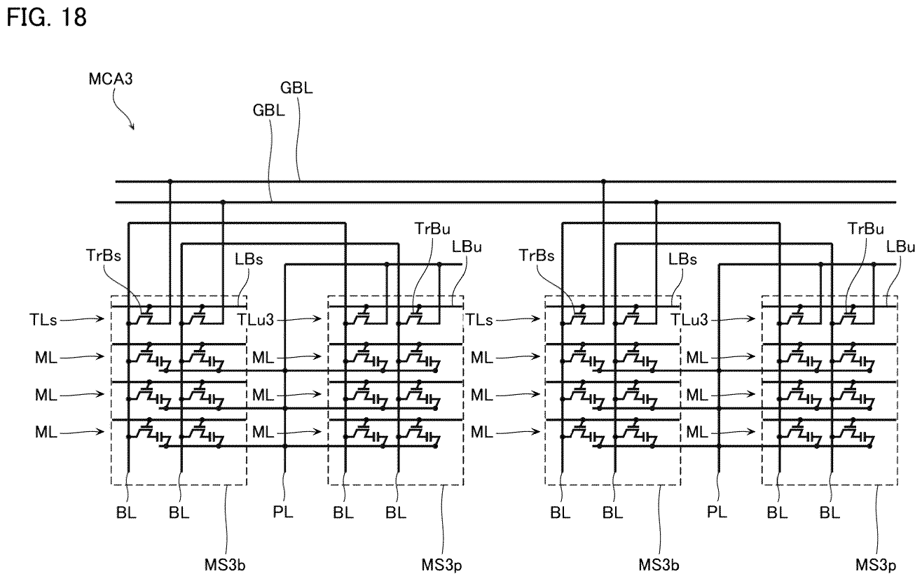

FIG. 18 is a schematic circuit diagram showing a part of a configuration of a semiconductor memory device according to a third embodiment. In the following description, portions similar to in the first embodiment will be assigned with the same symbols as in the first embodiment, and descriptions thereof omitted.

As shown in FIG. 18, the semiconductor memory device according to the present embodiment comprises a memory cell array MCA3. The memory cell array MCA3 comprises: a plurality of memory structures MS3b; a plurality of memory structures MS3p provided corresponding to these plurality of memory structures MS3b; and a plurality of the global bit lines GBL and the plate line PL that are connected to these pluralities of memory structures MS3b, MS3p.

The plurality of memory structures MS3b each comprise: a plurality of the memory layers ML; the transistor layer TLs; and a plurality of the bit lines BL connected to these plurality of memory layers ML and to the transistor layer TLs. These plurality of bit lines BL are electrically connected to corresponding global bit lines GBL via the transistors TrBs in the transistor layer TLs.

The plurality of memory structures MS3p each comprise: a plurality of the memory layers ML; a transistor layer TLu3; and a plurality of the bit lines BL connected to these plurality of memory layers ML and to the transistor layer TLu3. On the circuit diagram, the transistor layer TLu3 is configured similarly to the transistor layer TLu according to the first embodiment. The plurality of bit lines BL are electrically connected to the plate line PL via the transistors TrBu in the transistor layer TLu3. Moreover, these plurality of bit lines BL are connected to corresponding bit lines BL in their corresponding memory structure MS3b.

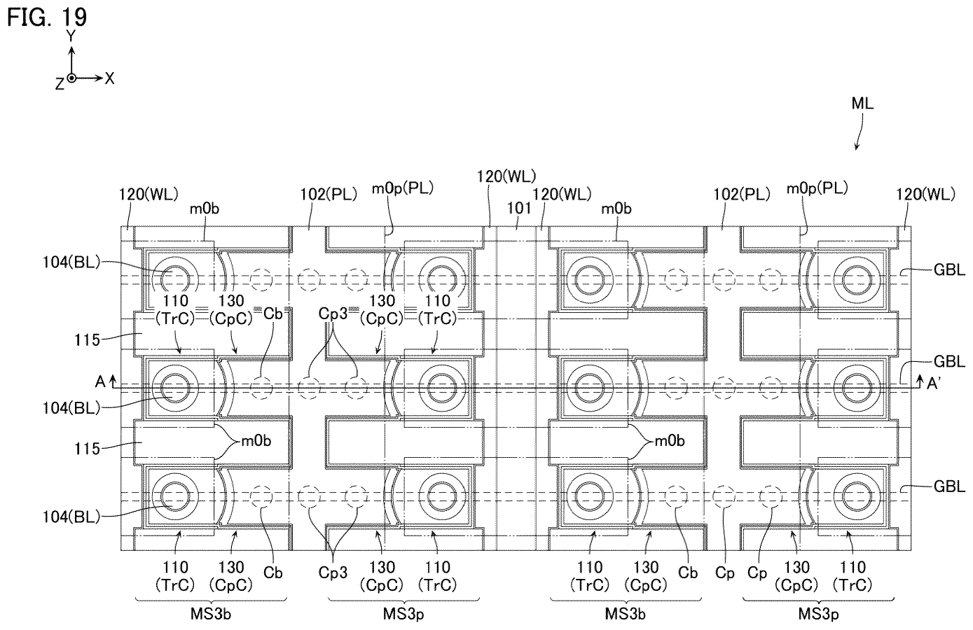

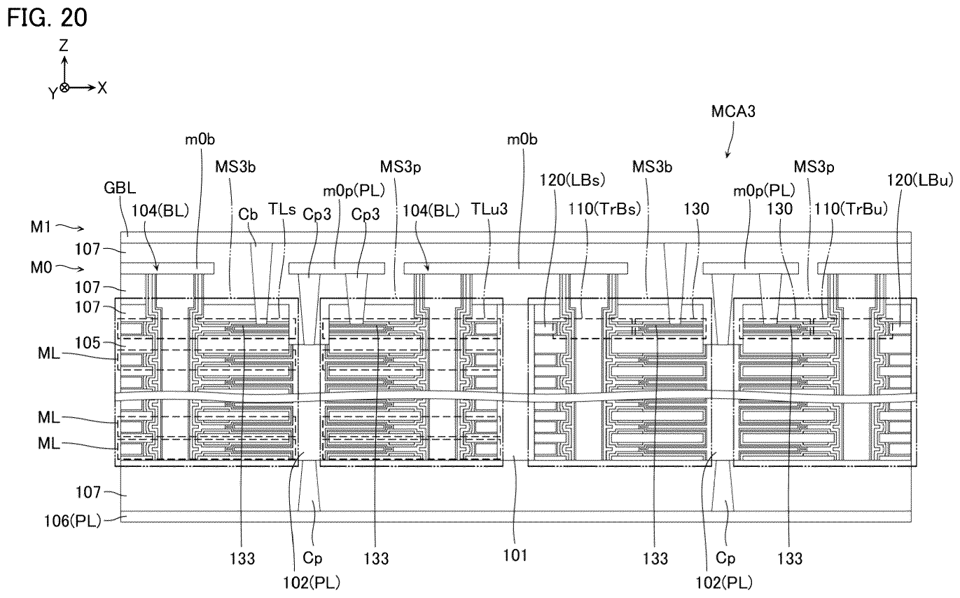

FIG. 19 is a schematic XY cross-sectional view showing a part of a configuration of the semiconductor memory device according to the present embodiment. In FIG. 19, the global bit line GBL, the contact electrodes Cb, and later-mentioned contact electrodes Cp3 are indicated by a dotted line. Moreover, in FIG. 19, later-mentioned wirings m0b, m0p in a wiring layer M0 are indicated by a two dot-chain line. FIG. 20 is a schematic cross-sectional view showing a part of a configuration of the semiconductor memory device according to the present embodiment. FIG. 20 shows a view in which the structure shown in FIG. 19 has been cut along the line A-A′ and viewed along a direction of the arrows.

As shown in FIG. 20, in the memory cell array MCA3, the pluralities of memory structures MS3b, MS3p are arranged alternately in the X-direction. Moreover, the insulating layer 101 is provided between the p^{th} (where p is an integer of 1 or more) memory structure MS3b counting from one side in the X-direction and the p^{th} memory structure MS3p counting from the one side in the X-direction. Moreover, the conductive layer 102 is provided between the p^{th} memory structure MS3p counting from the one side in the X-direction and the p+1^{th} memory structure MS3b counting from the one side in the X-direction. Moreover, a wiring layer M0 is provided above the pluralities of memory structures MS3b, MS3p, and a wiring layer M1 is provided above the wiring layer M0. The wiring layer M1 comprises a plurality of the global bit lines GBL. Moreover, the conductive layer 106, the contact electrodes Cp for connecting the conductive layer 106 and conductive layers 102, and the semiconductor substrate Sub (unillustrated in FIG. 20), are provided below the pluralities of memory structures MS3b, MS3p.

Moreover, the insulating layer 107 is provided between the plurality of memory structures MS and the wiring layer M0, and between the wiring layer M0 and the wiring layer M1.

The memory structure MS3b is basically configured similarly to the memory structure MS. However, the memory structure MS3b does not comprise the transistor layer TLu.

The memory structure MS3p is basically configured similarly to the memory structure MS. However, the memory structure MS3p does not comprise the transistor layer TLu. Moreover, the memory structure MS3p comprises the transistor layer TLu3 instead of the transistor layer TLs.

The transistor layer TLu3 is basically configured similarly to the transistor layer TLu. However, the transistor layer TLu3 is provided above the plurality of memory layers ML. Moreover, the conductive layer 133 in the transistor layer TLu3 is connected to the conductive layer 102 (plate line PL) via a pair of contact electrodes Cp3 and a wiring m0p.

As shown in FIG. 19, for example, the wiring layer M0 comprises: a plurality of wirings m0b provided corresponding to the pluralities of via wirings 104 in the memory structures MS3b, MS3p; and a plurality of the wirings m0p provided corresponding to a plurality of the conductive layers 102.

The wirings m0b are provided at respective positions that, viewed in the Z-direction, overlap one via wiring 104 in the p^{th} memory structure MS3b counting from the one side in the X-direction, and one via wiring 104 in the p^{th} memory structure MS3p counting from the one side in the X-direction. The wiring m0b is electrically connected to these corresponding two via wirings 104. In the example of FIG. 20, the wiring m0b is connected to upper ends of its corresponding two via wirings 104.

As shown in FIG. 19, for example, the wirings m0p are provided at respective positions that, viewed in the Z-direction, overlap the conductive layer 102 and all of the capacitor structures 130 in the memory structure MS3p. The wiring m0p is electrically connected to the conductive layer 102 and to the capacitor structures 130 in the memory structure MS3p, and functions as a part of the plate line PL. In the example of FIG. 19, the contact electrodes Cp3 are provided at positions where the wiring m0p and conductive layer 102 overlap viewed in the Z-direction, and at positions where the wiring m0p and capacitor structures 130 overlap viewed in the Z-direction. As shown in FIG. 20, one contact electrode Cp3 has its upper end connected to the wiring m0p, and has its lower end connected to the capacitor structure 130, more specifically, to the conductive layer 133 in the transistor layer TLu3. Moreover, the other contact electrode Cp3 has its upper end connected to the wiring m0p, and has its lower end connected to the conductive layer 102.

In the third embodiment, the via wirings 104 are electrically connected between two memory structures MS3b, MS3p adjacent in the X-direction. Hence, in the memory structure MS3b, it is possible for the conductive layers 133 in the transistor layer TLs provided above the plurality of memory layers ML to be connected to the global bit line GBL. Moreover, in the memory structure MS3p, it is possible for the conductive layers 133 in the transistor layer TLu provided above the plurality of memory layers ML to be connected to the plate line PL.

This kind of structure, too, can be realized with practically no increase in the number of manufacturing steps. Hence, the present embodiment, too, enables an easily manufacturable semiconductor memory device to be provided.

### Fourth Embodiment

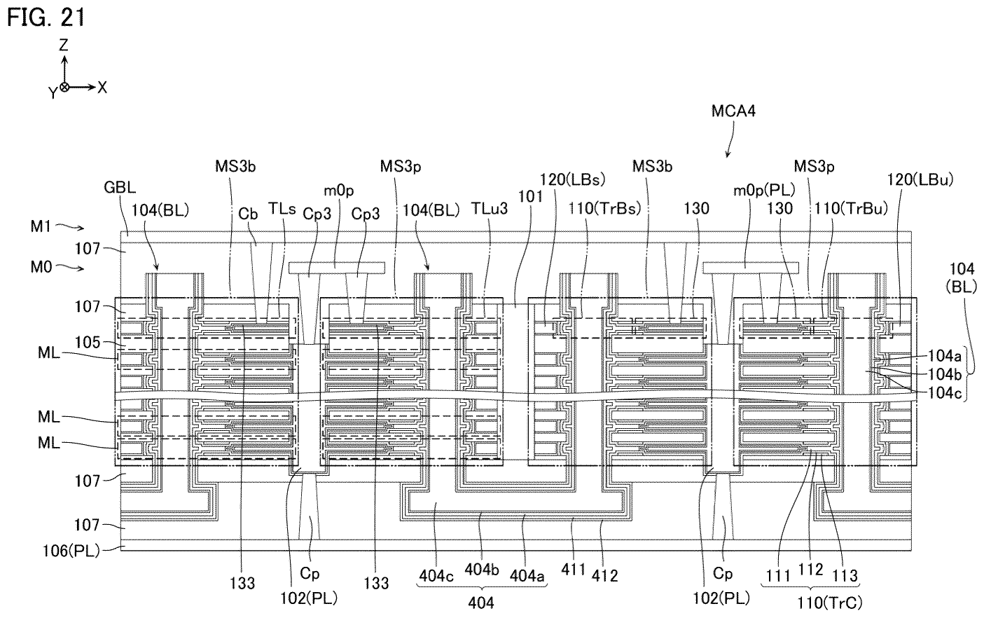

FIG. 21 is a schematic cross-sectional view showing a part of a configuration of a semiconductor memory device according to a fourth embodiment. In the following description, portions similar to in the third embodiment will be assigned with the same symbols as in the third embodiment, and descriptions thereof omitted.

The semiconductor memory device according to the fourth embodiment comprises a memory cell array MCA4. The memory cell array MCA4 is basically configured similarly to the memory cell array MCA3. However, the memory cell array MCA4 does not comprise the wiring m0b, but instead comprises a connecting structure 404. A plurality of the connecting structures 404 are provided corresponding to the pluralities of via wirings 104 in the memory structures MS3b, MS3p, similarly to the wirings m0b.

The connecting structures 404 are provided at respective positions that, viewed in the Z-direction, overlap one via wiring 104 in the p^{th} memory structure MS3b counting from the one side in the X-direction, and one via wiring 104 in the p^{th} memory structure MS3p counting from the one side in the X-direction. The connecting structure 404 is electrically connected to these corresponding two via wirings 104. In the example of FIG. 21, the connecting structure 404 is connected to lower ends of its corresponding two via wirings 104.

The connecting structure 404 includes, for example: a conductive oxide film 404a including a conductive oxide; a barrier conductive film 404b of the likes of titanium nitride (TiN); and a conductive member 404c of the likes of tungsten (W). The conductive oxide film 404a is continuous with the conductive oxide film 104a in the via wiring 104, and includes a similar material to the conductive oxide film 104a. The barrier conductive film 404b is continuous with the barrier conductive film 104b in the via wiring 104, and includes a similar material to the barrier conductive film 104b. The conductive member 404c is continuous with the conductive member 104c in the via wiring 104, and includes a similar material to the conductive member 104c.

Moreover, an upper surface, a lower surface, and an outer peripheral surface of the connecting structure 404 are covered by a semiconductor layer 411 and an insulating layer 412. The semiconductor layer 411 is continuous with the semiconductor layers 111 in the transistor structures 110, and includes a similar material to the semiconductor layers 111. The insulating layer 412 is continuous with the insulating layers 112 in the transistor structures 110, and includes a similar material to the insulating layer 112.

This kind of structure, too, can be realized with practically no increase in the number of manufacturing steps. Hence, the present embodiment, too, enables an easily manufacturable semiconductor memory device to be provided.

### Fifth Embodiment

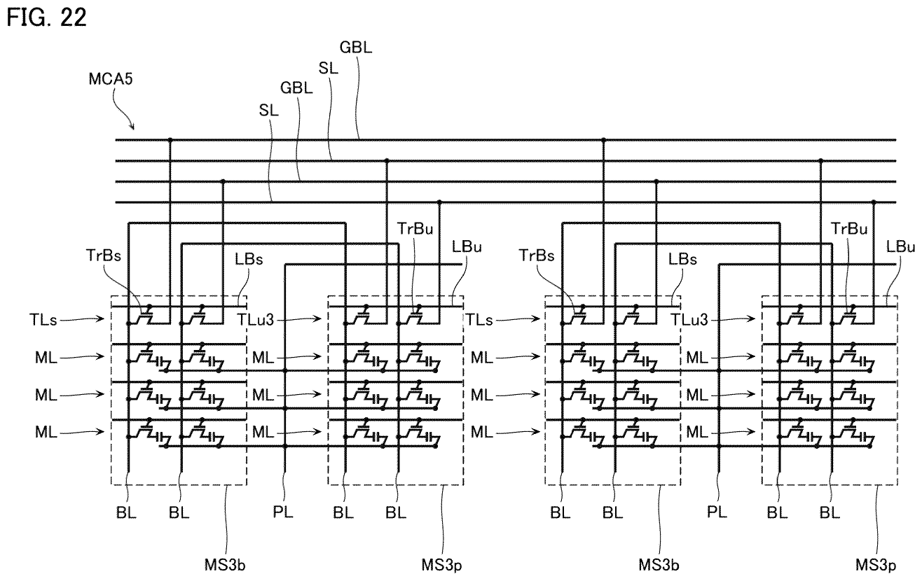

FIG. 22 is a schematic circuit diagram showing a part of a configuration of a semiconductor memory device according to a fifth embodiment. In the following description, portions similar to in the third embodiment will be assigned with the same symbols as in the third embodiment, and descriptions thereof omitted.

The semiconductor memory device according to the fifth embodiment is basically configured similarly to the semiconductor memory device according to the third embodiment. However, a memory cell array MCA5 according to the fifth embodiment comprises a plurality of shield lines SL connected to the plurality of memory structures MS. Moreover, in the fifth embodiment, one electrode of the transistor TrBu is connected to the shield line SL, not the plate line PL.

As will be mentioned in detail later, the shield lines SL are disposed alternately with the global bit lines GBL. Moreover, during the read operation, the shield line SL is applied with a certain fixed voltage. It therefore becomes possible that, during the read operation, effects of an electric field between adjacent global bit lines GBL are suppressed, and charge of the capacitor CpC is suitably read.

Moreover, during the read operation, the bit line select line LBu in the transistor layer TLu3 in a memory structure MS3p which has not been selected, is applied with the voltage V_{ON}. This makes it possible for the bit lines BL in the memory structures MS3b, MS3p that have not been selected, to be made electrically continuous with the shield line SL, and for voltage of the bit lines BL to be fixed, so that deterioration of charge holding characteristics of the memory cells MC will be suppressed.

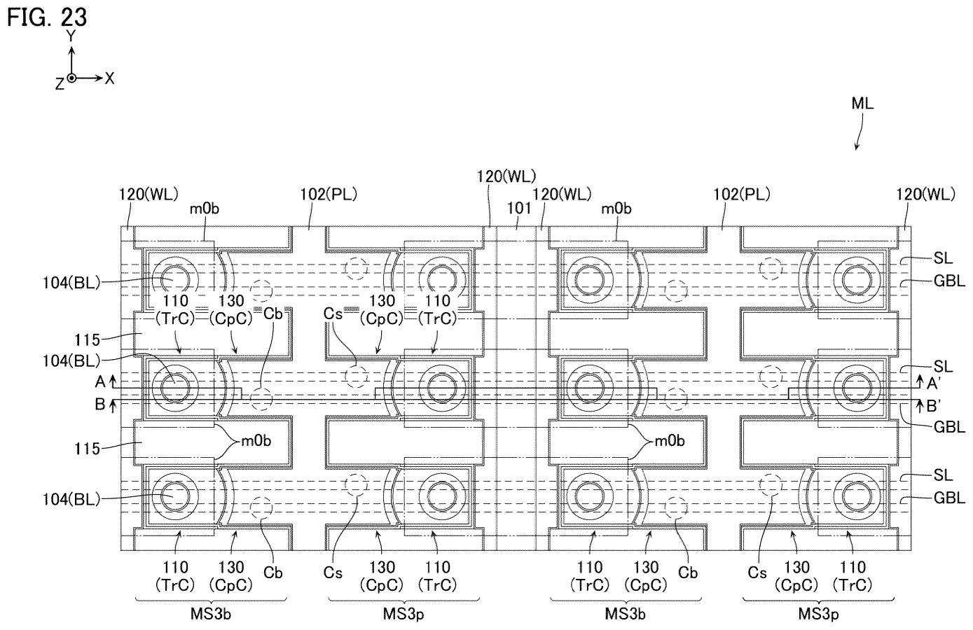

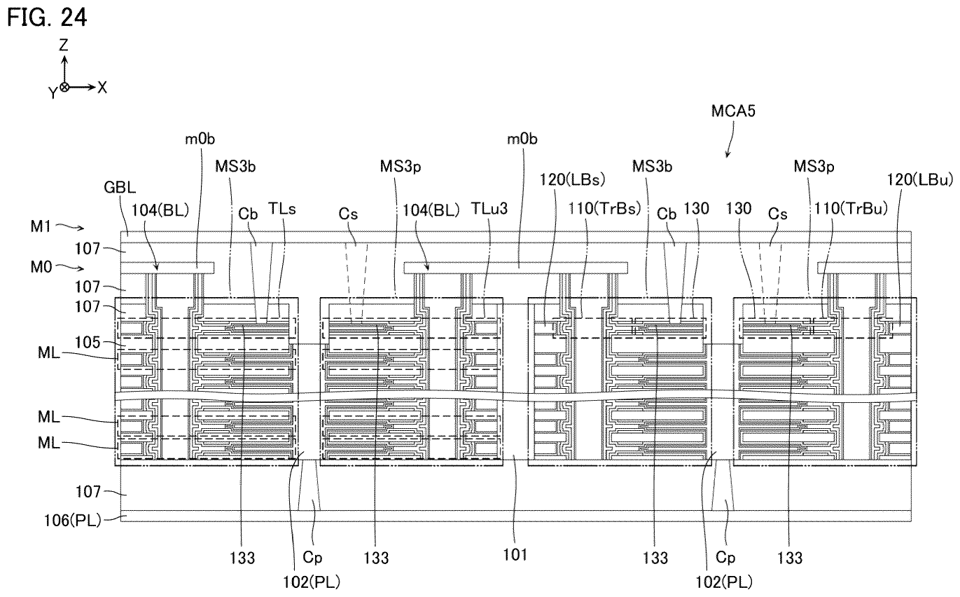

FIG. 23 is a schematic XY cross-sectional view showing a part of a configuration of the semiconductor memory device according to the fifth embodiment. In FIG. 23, the global bit lines GBL, the shield lines SL, the contact electrodes Cb, and a later-mentioned contact electrodes Cs are indicated by a dotted line. FIG. 24 is a schematic cross-sectional view showing a part of a configuration of the semiconductor memory device according to the present embodiment. FIG. 24 shows a view in which the structure shown in FIG. 23 has been cut along the line A-A′ and viewed along a direction of the arrows. However, at a height position corresponding to the global bit line GBL in FIG. 24, there is shown a view in which the structure shown in FIG. 23 has been cut along the line B-B′ and viewed along a direction of the arrows. Moreover, in FIG. 24, the contact electrode Cs provided at a position not corresponding to the line A-A′ in FIG. 23, is indicated by a dotted line.

The semiconductor memory device according to the fifth embodiment is basically configured similarly to the semiconductor memory device according to the third embodiment. However, as shown in FIG. 23, in the fifth embodiment, the wiring layer M1 is provided not only with a plurality of the global bit lines GBL, but also with a plurality of the shield lines SL. Moreover, the semiconductor memory device according to the fifth embodiment does not comprise the wiring m0p and the contact electrodes Cp3, but instead comprises contact electrodes Cs.

As shown in FIG. 23, the plurality of global bit lines GBL and the plurality of shield lines SL are arranged alternately in the Y-direction. The plurality of shield lines SL are each provided between two global bit lines GBL adjacent in the Y-direction, and extend in the X-direction. In the example illustrated, the shield lines SL are provided at positions that, viewed in the Z-direction, overlap the capacitor structures 130 electrically connected to its corresponding bit lines BL. Moreover, the contact electrodes Cs are provided at positions where the shield lines SL and the capacitor structures 130 overlap viewed in the Z-direction. The contact electrode Cs has its upper end connected to the shield line SL, and has its lower end connected to the capacitor structure 130, more specifically, to the conductive layer 133 in the transistor layer TLu3.

This kind of structure, too, can be realized with practically no increase in the number of manufacturing steps. Hence, the present embodiment, too, enables an easily manufacturable semiconductor memory device to be provided.

### Sixth Embodiment

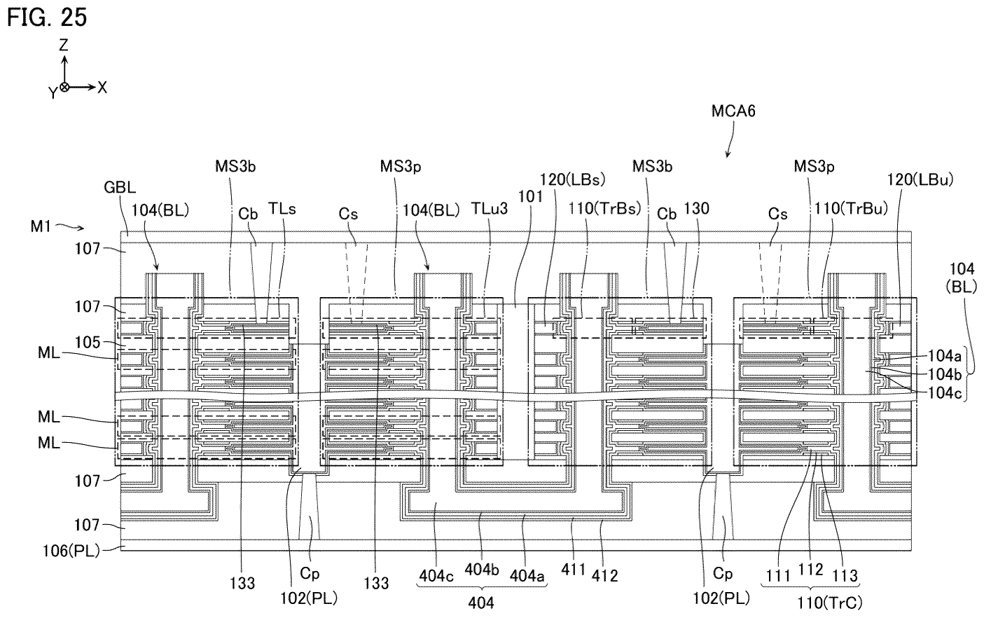

FIG. 25 is a schematic cross-sectional view showing a part of a configuration of a semiconductor memory device according to a sixth embodiment. In the following description, portions similar to in the fourth and fifth embodiments will be assigned with the same symbols as in the fourth and fifth embodiments, and descriptions thereof omitted.

The semiconductor memory device according to the sixth embodiment comprises a memory cell array MCA6. The memory cell array MCA6 is basically configured similarly to the memory cell array MCA5. However, the memory cell array MCA6 does not comprise the wiring layer M0, but instead comprises the connecting structure 404, similarly to in the fourth embodiment.

This kind of structure, too, can be realized with practically no increase in the number of manufacturing steps. Hence, the present embodiment, too, enables an easily manufacturable semiconductor memory device to be provided.

In particular, the semiconductor memory device according to the present embodiment does not include the wiring layer M0. It is therefore possible for the number of manufacturing steps to be reduced more compared to for the semiconductor memory device according to the fourth embodiment.

### Seventh Embodiment

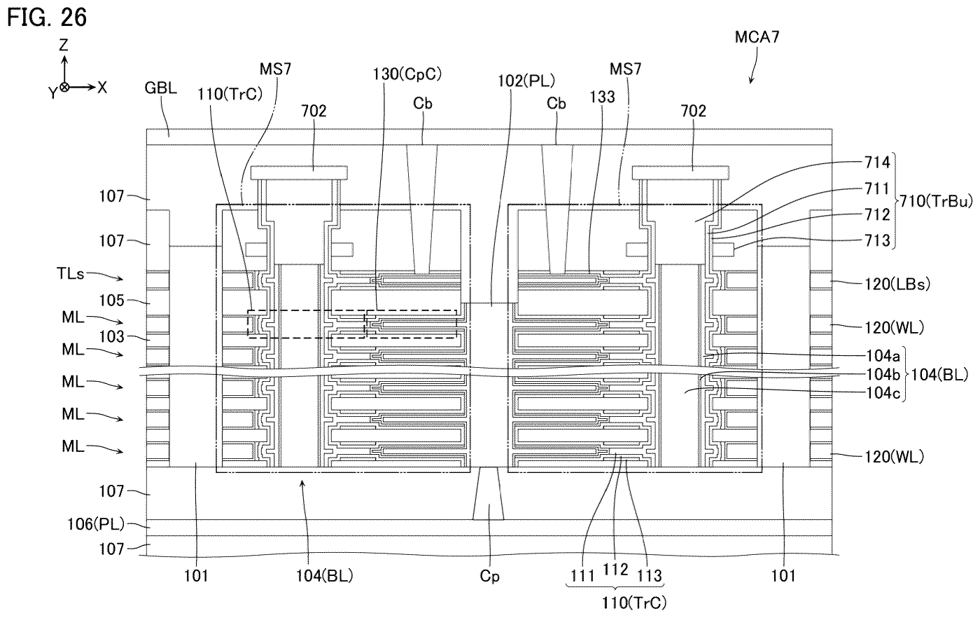

FIG. 26 is a schematic cross-sectional view showing a part of a configuration of a semiconductor memory device according to a seventh embodiment. In the following description, portions similar to in the first embodiment will be assigned with the same symbols as in the first embodiment, and descriptions thereof omitted.

The semiconductor memory device according to the seventh embodiment comprises a memory cell array MCA7. The memory cell array MCA7 is basically configured similarly to the memory cell array MCA. However, the memory cell array MCA7 comprises a memory structure MS7 instead of the memory structure MS. Moreover, between a plurality of the memory structures MS7 and a plurality of the global bit lines GBL, there are provided a plurality of wirings 702 that are provided corresponding to the plurality of memory structures MS7. Moreover, the memory cell array MCA7 does not comprise the contact electrode Cp connected to the conductive layer 106 and to the conductive layer 133 in the transistor layer TLu.

The memory structure MS7 is basically configured similarly to the memory structure MS. However, the memory structure MS7 does not comprise the transistor layer TLu. Moreover, the memory structure MS7 comprises a plurality of transistor structures 710 provided corresponding to the plurality of via wirings 104, and located above the via wirings 104.

The transistor structure 710 comprises: a cylindrical semiconductor layer 711 extending in the Z-direction; an insulating layer 712 extending in the Z-direction along an outer peripheral surface of the semiconductor layer 711; and a conductive layer 713 provided on an outer peripheral surface of the insulating layer 712. Moreover, a circular column-like insulating layer 714 extending in the Z-direction is provided in a center portion of the semiconductor layer 711. The insulating layer 714 includes the likes of silicon oxide (SiO), for example.

The semiconductor layer 711 functions as a channel region of the transistor TrBu. The semiconductor layer 711 is continuous with the semiconductor layer 111 in the transistor structure 110, and includes a similar material to the semiconductor layer 111.

The insulating layer 712 functions as a gate insulating film of the transistor TrBu. The insulating layer 712 is continuous with the insulating layer 112 in the transistor structure 110, and includes a similar material to the insulating layer 112.

The conductive layer 713 functions as the gate electrode of the transistor TrBu and as the bit line select line LBu (FIG. 1). The conductive layer 713 includes a barrier conductive film of the likes of titanium nitride (TiN), and a conductive member of the likes of tungsten (W), for example.

The wiring 702 extends in the Y-direction, and is commonly connected to the plurality of semiconductor layers 711 of a plurality of the transistor structures 710 arranged in the Y-direction. The wiring 702 includes a conductive oxide, for example. Moreover, the wiring 702 can include the likes of a stacked structure of titanium nitride (TiN) and tungsten (W), for example. During the read operation, the wiring 702 is applied with a certain fixed voltage.

### Other Embodiments

That concludes description of the semiconductor memory devices according to the first through seventh embodiments. However, the semiconductor memory devices according to these embodiments are merely exemplifications, and their specific configurations, and so on, may be appropriately adjusted.

For example, configurations in the memory cell arrays MCA, MCA2, MCA3, MCA4, MCA5, MCA6, MCA7 according to the first through seventh embodiments may be disposed vertically reversed. For example, in the case of the memory cell array MCA and control circuit being formed on separate substrates and bonded, as in the first embodiment, it is possible for the global bit line GBL to be disposed on a lower side, so that the global bit line GBL and sense amplifier circuit will be suitably connected. Moreover, it is possible for this kind of configuration to be adopted for the memory cell arrays MCA2, MCA3, MCA4, MCA5, MCA6, MCA7 according to the second through seventh embodiments, too.

Moreover, for example, in the first through seventh embodiments, as exemplified in the likes of FIGS. 3 and 23, positions of the via wirings 104 substantially match in two memory structures MS adjacent in the X-direction. However, such a configuration is merely an exemplification, and their specific arrangement may be appropriately adjusted.

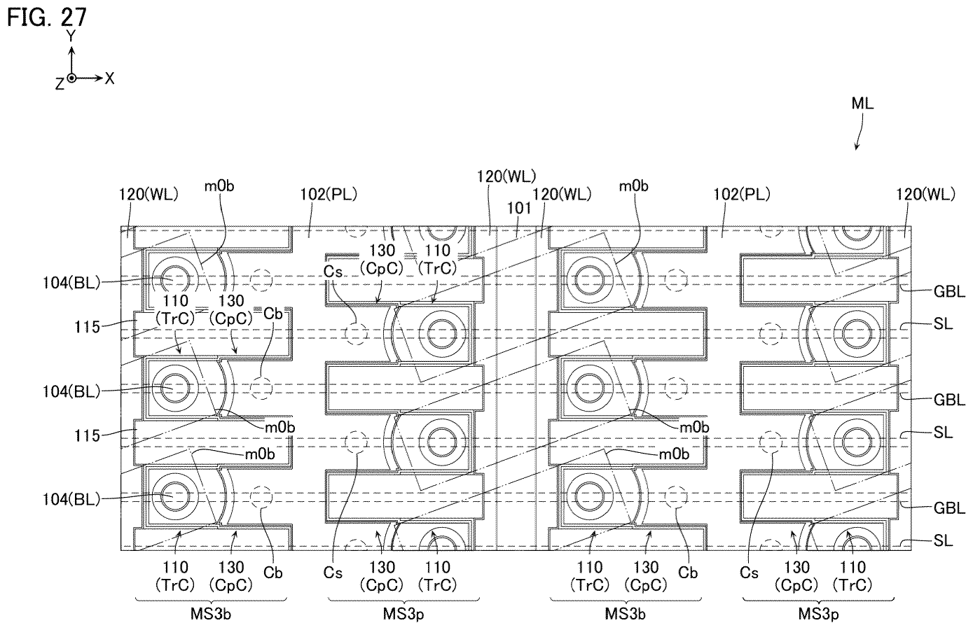

For example, in the example of FIG. 27, position of the via wiring 104 included in one memory structure MS3b of a pair of memory structures MS3b, MS3p adjacent in the X-direction and position of the insulating layer 115 included in the other memory structure MS3p of the pair of memory structures MS3b, MS3p adjacent in the X-direction match, and position of the insulating layer 115 included in the one memory structure MS3b of the pair of memory structures MS3b, MS3p adjacent in the X-direction and position of the via wiring 104 included in the other memory structure MS3p of the pair of memory structures MS3b, MS3p adjacent in the X-direction match. Due to such a configuration, it is possible for center positions in the Y-direction of the global bit lines GBL, via wirings 104, and contact electrodes Cb to be matched, so that the global bit lines GBL will be disposed equally spaced in the Y-direction. Moreover, in configurations including the shield line SL, as in the fifth and sixth embodiments, it is possible for center positions in the Y-direction of the shield lines SL, via wirings 104, and contact electrodes Cb to be matched, so that the shield lines SL will be disposed equally spaced in the Y-direction.

Moreover, in the semiconductor memory devices according to the first through seventh embodiments, the via wiring 104 functioning as the bit line BL includes a conductive oxide such as indium tin oxide (ITO). However, such a conductive oxide may be included in the transistor structure 110, rather than in the via wiring 104 extending in the Z-direction. Moreover, the via wiring 104 and the transistor structure 110 may include another material, or the like.

Moreover, in the semiconductor memory devices according to the first through seventh embodiments, the conductive layer 113 functioning as the gate electrode of the transistor TrC may face only one of the upper surface and lower surface, of the semiconductor layer 111 functioning as the channel region of the transistor TrC.

Moreover, in the above description, there is described an example where the capacitor CpC is adopted as the memory portion connected to the transistor structure 110. Moreover, in the above description, there is described an example where the memory portion includes one electrode, the other electrode facing this one electrode, and the memory film provided between these one electrode and other electrode, and the memory film is an insulating metal oxide. However, the memory portion need not be the capacitor CpC, and the memory film need not be the insulating metal oxide. For example, the memory film may include a ferroelectric material, a ferromagnetic material, a chalcogen material of the likes of GeSbTe, or another material. Moreover, the memory portion may utilize characteristics of these materials to store data.

### Others

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a plurality of first semiconductor layers stacked in a first direction;
a via wiring which extends in the first direction, and is electrically connected to the plurality of first semiconductor layers;
a plurality of memory portions which are arranged in the first direction corresponding to the plurality of first semiconductor layers, and are electrically connected to the plurality of first semiconductor layers;
a plurality of first gate electrodes which are arranged in the first direction corresponding to the plurality of first semiconductor layers, and face the plurality of first semiconductor layers;
a first wiring provided on one side in the first direction with respect to the plurality of first semiconductor layers;
a second semiconductor layer which is provided between the plurality of first semiconductor layers and the first wiring, and is electrically connected to the via wiring;
a first connecting electrode which is provided between the plurality of memory portions and the first wiring, and is electrically connected to the first wiring and the second semiconductor layer;
a second gate electrode which is provided between the plurality of first gate electrodes and the first wiring, and faces the second semiconductor layer;
a second wiring provided on the other side in the first direction with respect to the plurality of first semiconductor layers;
a third semiconductor layer which is provided between the plurality of first semiconductor layers and the second wiring, and is electrically connected to the via wiring;
a second connecting electrode which is provided between the plurality of memory portions and the second wiring, and is electrically connected to the second wiring and the third semiconductor layer; and
a third gate electrode which is provided between the plurality of first gate electrodes and the second wiring, and faces the third semiconductor layer.

2. The semiconductor memory device according to claim 1, comprising:
a first contact electrode which is provided between the first wiring and the first connecting electrode, extends in the first direction, and is electrically connected to the first wiring and the first connecting electrode; and
a second contact electrode which is provided between the second wiring and the second connecting electrode, extends in the first direction, and is electrically connected to the second wiring and the second connecting electrode.

3. The semiconductor memory device according to claim 1, wherein
the plurality of memory portions each comprise:
a first electrode electrically connected to a corresponding one of the plurality of first semiconductor layers;
a second electrode facing the first electrode; and
a memory film provided between the first electrode and the second electrode, and
the second electrode is electrically connected to the second wiring.

4. The semiconductor memory device according to claim 1, wherein
the first semiconductor layer and the second semiconductor layer each include: at least one element of gallium (Ga) or aluminum (Al); indium (In); zinc (Zn); and
oxygen (O).

5. The semiconductor memory device according to claim 1, comprising
a plurality of third wirings which are arranged in the first direction corresponding to the plurality of first semiconductor layers, and are electrically connected to the plurality of first gate electrodes, wherein
the first gate electrode faces one or both of a surface on one side in the first direction and a surface on the other side in the first direction, of the first semiconductor layer,
the plurality of memory portions are provided on one side in a second direction intersecting the first direction, with respect to the plurality of the first semiconductor layers, and
the plurality of third wirings are provided on the other side in the second direction, with respect to the plurality of the first semiconductor layers.

6. A semiconductor memory device comprising:
a plurality of first semiconductor layers stacked in a first direction;
a via wiring which extends in the first direction, and is electrically connected to the plurality of first semiconductor layers;
a plurality of memory portions which are arranged in the first direction corresponding to the plurality of first semiconductor layers, and are electrically connected to the plurality of first semiconductor layers;
a plurality of first gate electrodes which are arranged in the first direction corresponding to the plurality of first semiconductor layers, and face the plurality of first semiconductor layers;
a first wiring which is provided on one side in the first direction with respect to the plurality of first semiconductor layers, and extends in a second direction intersecting the first direction;
a second semiconductor layer which is provided between the plurality of first semiconductor layers and the first wiring, and is electrically connected to the via wiring;
a first connecting electrode which is provided between the plurality of memory portions and the first wiring, and is electrically connected to the first wiring and the second semiconductor layer;
a second gate electrode which is provided between the plurality of first gate electrodes and the first wiring, and faces the second semiconductor layer;
a second wiring which extends in the first direction, and is arranged with the plurality of first semiconductor layers in the second direction;
a third semiconductor layer which is provided at a position overlapping the plurality of first semiconductor layers when viewed in the first direction, and is electrically connected to the via wiring;
a second connecting electrode which is provided at a position overlapping the plurality of memory portions when viewed in the first direction, and is electrically connected to the third semiconductor layer and the second wiring; and
a third gate electrode which is provided at a position overlapping the plurality of first gate electrodes when viewed in the first direction, and faces the third semiconductor layer.

7. The semiconductor memory device according to claim 6, wherein
the plurality of memory portions each comprise:
a first electrode whose end portion on one side in the second direction is electrically connected to a corresponding one of the plurality of first semiconductor layers;
a second electrode whose end portion on the other side in the second direction is connected to the second wiring, and that faces the first electrode in the first direction; and
a memory film provided between the first electrode and the second electrode, and
an end portion of the second connecting electrode on one side in the second direction is connected to the third semiconductor layer, and another end portion of the second connecting electrode on the other side in the second direction is connected to the second wiring.

8. The semiconductor memory device according to claim 6, wherein
a part of the plurality of first semiconductor layers is provided on one side in the first direction with respect to the third semiconductor layer, and
the other part of the plurality of first semiconductor layers is provided on the other side in the first direction with respect to the third semiconductor layer.

9. The semiconductor memory device according to claim 6, wherein
the first semiconductor layer and the second semiconductor layer each include: at least one element of gallium (Ga) or aluminum (Al); indium (In); zinc (Zn); and
oxygen (O).

10. The semiconductor memory device according to claim 6, comprising
a plurality of third wirings which are arranged in the first direction corresponding to the plurality of first semiconductor layers, and are electrically connected to the plurality of first gate electrodes, wherein
the first gate electrode faces one or both of a surface on one side in the first direction and a surface on the other side in the first direction, of the first semiconductor layer,
the plurality of memory portions are provided on one side in the second direction, with respect to the plurality of first semiconductor layers, and
the plurality of third wirings are provided on the other side in the second direction, with respect to the plurality of first semiconductor layers.

11. A semiconductor memory device comprising
a pair of memory structures and a first wiring separated from the pair of memory structures in a first direction, wherein
the pair of memory structures is arranged in a second direction intersecting the first direction,
the pair of memory structures each comprise:
a plurality of first semiconductor layers stacked in the first direction;
a via wiring which extends in the first direction, and is electrically connected to the plurality of first semiconductor layers;
a plurality of memory portions which are arranged in the first direction corresponding to the plurality of first semiconductor layers, and are electrically connected to the plurality of first semiconductor layers;
a plurality of first gate electrodes which are arranged in the first direction corresponding to the plurality of first semiconductor layers, and face the plurality of first semiconductor layers;
a second semiconductor layer which is provided between the plurality of first semiconductor layers and the first wiring, and is electrically connected to the via wiring;
a connecting electrode which is provided between the plurality of memory portions and the first wiring, and is electrically connected to the second semiconductor layer; and
a second gate electrode which is provided between the plurality of first gate electrodes and the first wiring, and faces the second semiconductor layer,
the connecting electrode included in one of the pair of memory structures being electrically connected to the first wiring, and
the via wiring included in the one of the pair of memory structures being electrically connected to the via wiring included in the other of the pair of memory structures.

12. The semiconductor memory device according to claim 11, comprising
a second wiring provided between the pair of memory structures, wherein
the connecting electrode included in the other of the pair of memory structures is electrically connected to the second wiring.

13. The semiconductor memory device according to claim 12, comprising:
a fourth wiring which is provided between the pair of memory structures and the first wiring;
a contact electrode which is provided between the connecting electrode included in the other of the pair of memory structures and the fourth wiring, extends in the first direction, and is electrically connected to the connecting electrode included in the other of the pair of memory structures and to the fourth wiring; and
another contact electrode which is provided between the second wiring and the fourth wiring, extends in the first direction, and is electrically connected to the second wiring and the fourth wiring.

14. The semiconductor memory device according to claim 11, comprising
a fifth wiring which is arranged with the first wiring in a third direction intersecting the first direction and the second direction, the first wiring and the fifth wiring each extending in the second direction, wherein
the connecting electrode included in the other of the pair of memory structures is electrically connected to the fifth wiring.

15. The semiconductor memory device according to claim 11, comprising
a sixth wiring which is provided between the pair of memory structures and the first wiring, wherein
the via wirings included in the pair of memory structures are electrically connected to each other via the sixth wiring.

16. The semiconductor memory device according to claim 11, comprising
a connecting structure provided on an opposite side to the first wiring in the first direction, with respect to the pair of memory structures, wherein
the via wirings included in the pair of memory structures are electrically connected to each other via the connecting structure.

17. The semiconductor memory device according to claim 11, wherein
the first semiconductor layer and the second semiconductor layer each include: at least one element of gallium (Ga) or aluminum (Al); indium (In); zinc (Zn); and
oxygen (O).

18. The semiconductor memory device according to claim 11, wherein
the pair of memory structures each comprise a plurality of third wirings which are arranged in the first direction corresponding to the plurality of first semiconductor layers, and are electrically connected to the plurality of first gate electrodes,
the first gate electrode faces one or both of a surface on one side in the first direction and a surface on the other side in the first direction, of the first semiconductor layer,
the plurality of memory portions are provided on one side in the second direction, with respect to the plurality of first semiconductor layers, and
the plurality of third wirings are provided on the other side in the second direction, with respect to the plurality of first semiconductor layers.

19. A semiconductor memory device comprising:
a plurality of first semiconductor layers stacked in a first direction;
a via wiring which extends in the first direction, and is electrically connected to the plurality of first semiconductor layers;
a plurality of memory portions which are arranged in the first direction corresponding to the plurality of first semiconductor layers, and are electrically connected to the plurality of first semiconductor layers;
a plurality of first gate electrodes which are arranged in the first direction corresponding to the plurality of first semiconductor layers, and face the plurality of first semiconductor layers;
a first wiring provided on one side in the first direction with respect to the plurality of first semiconductor layers;
a second semiconductor layer which is provided between the plurality of first semiconductor layers and the first wiring, and is electrically connected to the via wiring;
a first connecting electrode which is provided between the plurality of memory portions and the first wiring, and is electrically connected to the first wiring and the second semiconductor layer;
a second gate electrode which is provided between the plurality of first gate electrodes and the first wiring, and faces the second semiconductor layer;
a second wiring provided between the first wiring and the second semiconductor layer;
a third semiconductor layer which is provided between the via wiring and the second wiring, and is electrically connected to the via wiring and the second wiring; and
a third gate electrode which is provided between the via wiring and the second wiring, and faces an outer peripheral surface of the third semiconductor layer.

20. The semiconductor memory device according to claim 19, wherein
the first semiconductor layer and the second semiconductor layer each include: at least one element of gallium (Ga) or aluminum (Al); indium (In); zinc (Zn); and
oxygen (O).

21. The semiconductor memory device according to claim 19, comprising
a plurality of third wirings which are arranged in the first direction corresponding to the plurality of first semiconductor layers, and are electrically connected to the plurality of first gate electrodes, wherein
the first gate electrode faces one or both of a surface on one side in the first direction and a surface on the other side in the first direction, of the first semiconductor layer,
the plurality of memory portions are provided on one side in a second direction intersecting the first direction, with respect to the plurality of first semiconductor layers, and
the plurality of third wirings are provided on the other side in the second direction, with respect to the plurality of first semiconductor layers.
